(19) United States
(12) Patent Application Publication
(10) Pub. No.: US 2005/0098107 A1
(43) Pub. Date: May 12, 2005

(54) Thermal processing system with cross-flow liner

(76) Inventors: Dale R. Du Bois, Los Gatos, CA (US); Cole Porter, San Jose, CA (US); Martin Mogaard, Scotts Valley, CA (US); Robert Jeffrey Bailey, Scotts Valley, CA (US)

Correspondence Address: Maria S. Swiatek;DORSEY & WHITNEY LLP, Suite 3400, 4 Embarcadero Center, San Francisco, CA, 94111, US

(21) Appl. No.: 10/947,426

(22) Filed: Sep. 21, 2004

Related U.S. Application Data
(60) Provisional application No. 60/505,833, filed on Sep. 24, 2003.

(51) Int. Cl. C23C 16/00

(52) U.S. Cl. 118/715

(57) ABSTRACT

An apparatus is provided for thermally processing substrates held in a carrier. The apparatus includes a cross-flow liner to improve gas flow uniformity across the surface of each substrate. The cross-flow liner of the present invention includes a longitudinal bulging section to accommodate a cross-flow injection system. The liner is patterned and sized so that it is conformal to the wafer carrier, and as a result, reduces the gap between the liner and the wafer carrier to reduce or eliminate vortices and stagnation in the gap areas between the wafer carrier and the liner inner wall.

### CROSS REFERENCE TO RELATED APPLICATION

This application claims the benefit of and priority to U.S. Provisional Patent Application No. 60/505,833 filed Sep. 24, 2003, the disclosure of which is hereby incorporated by reference in its entirety, and is related to PCT application Serial No. PCT/US03/21575 entitled Thermal Processing System and Configurable Vertical Chamber, which claims priority to U.S. Provisional patent application Ser. Nos. 60/396,536 and 60/428,526, the disclosures of all of which are hereby incorporated by reference in their entirety.

### TECHNICAL FIELD

The present invention relates generally to systems and methods for heat-treating objects, such as substrates. More specifically, the present invention relates to an apparatus and method for heat treating, annealing, and depositing layers of material on or removing layers of material from a semiconductor wafer or substrate.

### BACKGROUND

Thermal processing apparatuses are commonly used in the manufacture of integrated circuits (ICs) or semiconductor devices from semiconductor substrates or wafers. Thermal processing of semiconductor wafers include, for example, heat treating, annealing, diffusion or driving of dopant material, deposition or growth of layers of material, and etching or removal of material from the substrate. These processes often call for the wafer to be heated to a temperature as high as 1300° C. and as low as 300° C. before and during the process, and that one or more fluids, such as a process gas or reactant, be delivered to the wafer. Moreover, these processes typically require that the wafer be maintained at a uniform temperature throughout the process, despite variations in the temperature of the process gas or the rate at which it is introduced into the process chamber.

A conventional thermal processing apparatus typically consists of a voluminous process chamber positioned in or surrounded by a furnace. Substrates to be thermally processed are sealed in the process chamber, which is then heated by the furnace to a desired temperature at which the processing is performed. For many processes, such as Chemical Vapor Deposition (CVD), the sealed process chamber is first evacuated, and once the process chamber has reached the desired temperature a reactive or process gases are introduced to form or deposit reactant species on the substrates.

In the past, thermal processing apparatus typically and in particular vertical thermal processing apparatuses, required guard heaters disposed adjacent to sidewalls of the process chamber above and below the process zone in which product wafers were processed. This arrangement is undesirable since it entails a larger chamber volume that must be pumped down, filled with process gas or vapor, and backfilled or purged, resulting in increased processing time. Moreover, this configuration takes up a tremendous amount of space and power due to a poor view factor of the wafers from the heaters.

Other problems with conventional thermal processing apparatuses include the considerable time required both before processing to ramp up the temperature of the process chamber and the wafer to be treated, and the time required after processing to ramp down the temperature. Furthermore, additional time is often required to ensure the temperature of the process chamber has stabilized uniformly at the desired temperature before processing can begin. While the actual time required for processing of the wafers may be half hour or less, pre- and post-processing times typically take 1 to 3 hours or longer. Thus, the time required to quickly ramp up and/or down the temperature of the process chamber to a uniform temperature significantly limits the throughput of the conventional thermal processing apparatus.

A fundamental reason for the relatively long ramp up and ramp down times is the thermal mass of the process chamber and/or furnace in conventional thermal processing apparatuses, which must be heated or cooled prior to effectively heating or cooling the wafer.

A common approach to minimizing or offsetting this limitation on throughput of conventional thermal processing apparatus has been to increase the number of wafers capable of being processed in a single cycle or run. Simultaneous processing of a large number of wafers helps to maximize the effective throughput of the apparatus by reducing the effective processing time on a per wafer basis. However, this approach also increases the magnitude of the risk should something go wrong during processing. That is a larger number of wafers could be destroyed or damaged by a single failure, for example, if there was an equipment or process failure during a single processing cycle. This is particularly a concern with larger wafer sizes and more complex integrated circuits where a single wafer could be valued at from $1,000 to $10,000 depending on the stage of processing.

Another problem with this solution is that increasing the size of the process chamber to accommodate a larger number of wafers increases the thermal mass effects of the process chamber, thereby reducing the rate at which the wafer can be heated or cooled. Moreover, larger process chambers processing larger batches of wafers leads to or compounds a first-in-last-out syndrome in which the first wafers loaded into the chamber are also the last wafers removed, resulting in these wafers being exposed to elevated temperatures for longer periods and reducing uniformity across the batch of wafers.

Another problem with the above approach is that systems and apparatuses used for many of the processes before and after thermal processing are not amenable to simultaneous processing of large numbers of wafers. Thus, thermal processing of large batches or large numbers wafers, while increasing the throughput of the thermal processing apparatus, can do little to improve the overall throughput of the semiconductor fabrication facility and may actually reduce it by requiring wafers to accumulate ahead of the thermal processing apparatus or causing wafers to bottleneck at other systems and apparatuses downstream therefrom.

An alternative to the conventional thermal processing apparatus described above, are rapid thermal processing (RTP) systems that have been developed for rapidly thermal processing of wafers. Conventional RTP systems generally use high intensity lamps to selectively heat a single wafer or small number of wafers within a small, transparent, usually quartz, process chamber. RTP systems minimize or eliminate the thermal mass effects of the process chamber, and since the lamps have very low thermal mass, the wafer can be heated and cooled rapidly by instantly turning the lamps on or off.

Unfortunately, conventional RTP systems have significant shortcomings including the placement of the lamps, which in the past were arranged in zones or banks each consisting of a number of lamps adjacent to sidewalls of the process chamber. This configuration is problematic because it takes up a tremendous amount of space and power in order to be effective due to their poor view factor, all of which are at a premium in the latest generation of semiconductor processing equipment.

Another problem with conventional RTP systems is their inability to provide uniform temperature distribution across multiple wafers within a single batch of wafers and even across a single wafer. There are several reasons for this non-uniform temperature distribution including (i) a poor view factor of one or more of the wafers by one or more of the lamps, and (ii) variation in output power from the lamps.

Moreover, failure or variation in the output of a single lamp can adversely affect the temperature distribution across the wafer. Because of this in most lamp-based systems, the wafer or wafers are rotated to ensure that the temperature non-uniformity due to the variation in lamp output is not transferred to the wafer during processing. However, the moving parts required to rotate the wafer, particularly the rotating feedthrough into the process chamber, adds to the cost and complexity of the system, and reduces the overall reliability thereof.

Yet another troublesome area for RTP systems is in maintaining uniform temperature distribution across the outer edges and the center of the wafer. Most conventional RTP systems have no adequate means to adjust for this type of temperature non-uniformity. As a result, transient temperature fluctuations occur across the surface of the wafer that can cause the formation of slip dislocations in the wafer at high temperatures, unless a black body susceptor is used that is larger in diameter than the wafer.

Conventional lamp-based RTP systems have other drawbacks. For example; there are no adequate means for providing uniform power distribution and temperature uniformity during transient periods, such as when the lamps are powered on and off, unless phase angle control is used which produces electrical noise. Repeatability of performance is also usually a drawback of lamp-based systems, since each lamp tends to perform differently as it ages. Replacing lamps can also be costly and time consuming, especially when one considers that a given lamp system may have upwards of 180 lamps. The power requirement may also be costly, since the lamps may have a peak power consumption of about 250 kWatts.

Accordingly, there is a need for an apparatus and method for quickly and uniformly heating a batch of one or more substrates to a desired temperature across the surface of each substrate in the batch of during thermal processing.

### SUMMARY OF THE INVENTION

The present invention provides a solution to these and other problems, and offers other advantages over the prior art.

The present invention provides an apparatus and method for isothermally heating work pieces, such as semiconductor substrates or wafers, for performing processes such as annealing, diffusion or driving of dopant material, deposition or growth of layers of material, and etching or removal of material from the wafer.

A thermal processing apparatus is provided for processing substrates held in a carrier at high or elevated temperatures. The apparatus includes a process chamber having a top wall, a side wall and a bottom wall, and a heating source having a number of heating elements proximal to the top wall, the side wall and the bottom wall of the process chamber to provide an isothermal environment in a process zone in which the carrier is positioned to thermally process the substrates. According to one aspect, the dimensions of the process chamber are selected to enclose a volume substantially no larger than a volume necessary to accommodate the carrier, and the process zone extends substantially throughout the process chamber. Preferably, the process chamber has dimensions selected to enclose a volume substantially no larger than 125% of that necessary to accommodate the carrier. More preferably, the apparatus further includes a pumping system to evacuate the process chamber prior to processing pressure and a purge system to backfill the process chamber after processing is complete, and the dimensions of the process chamber are selected to provide both a rapid evacuation and a rapid backfilling of the process chamber.

According to another aspect of the invention, the bottom wall of the process chamber includes a movable pedestal having at least one heating element therein, and the movable pedestal is adapted to be lowered and raised to enable the carrier with the substrates to be inserted into and removed from the process chamber. In one embodiment, the apparatus further includes a removable thermal shield adapted to be inserted between heating element in the pedestal and the substrates held the carrier. The thermal shield is adapted to reflect thermal energy from the heating element in the pedestal back to the pedestal, and to shield the substrates on the carrier from thermal energy from the heating element in the pedestal. In one version of this embodiment, the apparatus further includes a shutter adapted to be moved into place above the carrier to isolate the process chamber when the pedestal is in a lowered position. Where the apparatus includes a pumping system to evacuate the process chamber, and the shutter can be adapted to seal with the process chamber, thereby enabling the pumping system to evacuate the process chamber when the pedestal is in the lowered position.

In yet another embodiment, the apparatus further includes a magnetically coupled repositioning system that repositions the carrier during thermal processing of the substrates. Preferably, the mechanical energy used to reposition the carrier is magnetically coupled through the pedestal to the carrier without use of a movable feedthrough into the process chamber, and substantially without moving the heating element in the pedestal. More preferably, the magnetically coupled repositioning system is a magnetically coupled rotation system that rotates the carrier within the process zone during thermal processing of the substrates.

According to another aspect of the present invention, the apparatus further comprises a cross-flow liner to improve gas flow uniformity across the surface of each substrate. The cross-flow liner of the present invention includes a longitudinal bulging section to accommodate a cross-flow injection system. The liner is patterned and sized so that it is conformal to the wafer carrier to reduce the gap between the liner and the wafer carrier, and as a result, the vortices or stagnation in the gap regions that are detrimental to manufacturing processes are reduced or eliminated.

### BRIEF DESCRIPTION OF THE DRAWINGS

These and various other features and advantages of the present invention will be apparent upon reading of the following detailed description in conjunction with the accompanying drawings and the appended claims provided below, where:

FIG. 1 is a cross-sectional view of a thermal processing apparatus having a pedestal heater for providing an isothermal control volume according to an embodiment of the present invention, employing conventional up-flow configuration;

FIG. 2 is a perspective view of an alternative embodiment a base-plate useful in the thermal processing apparatus shown in FIG. 1;

FIG. 3 is a cross-sectional view of a portion of a thermal processing apparatus having a pedestal heater and a thermal shield according to an embodiment of the present invention;

FIG. 4 is a diagrammatic illustration of the pedestal heater and thermal shield of FIG. 3 according to an embodiment of the present invention;

FIG. 5 is a diagrammatic illustration of an embodiment of the thermal shield having a top layer of material with a high absorptivity and a lower layer of material with a high reflectivity according to present invention;

FIG. 6 is a diagrammatic illustration of another embodiment of the thermal shield having a cooling channel according to present invention;

FIG. 7 is a perspective view of an embodiment of a thermal shield and an actuator according to present invention;

FIG. 8 is a cross-sectional view of a portion of a thermal processing apparatus having a shutter according to an embodiment of the present invention;

FIG. 9 is a cross-sectional view of a process chamber having a pedestal heater and a magnetically coupled wafer rotation system according to an embodiment of the present invention;

FIG. 10 is a cross-sectional view of a thermal processing apparatus having a cross-flow injector system according to an embodiment of the present invention;

FIG. 11 is a cross-sectional side view of a portion of the thermal processing apparatus of FIG. 10 showing positions of injector orifices in relation to the liner and of exhaust slots in relation to the wafers according to an embodiment of the present invention;

FIG. 12 is a plan view of a portion of the thermal processing apparatus of FIG. 10 taken along the line A-A of FIG. 10 showing gas flow from orifices of a primary and a secondary injector across a wafer and to an exhaust port according to an embodiment of the present invention;

FIG. 13 is a plan view of a portion of the thermal processing apparatus of FIG. 10 taken along the line A-A of FIG. 10 showing gas flow from orifices of a primary and a secondary injector across a wafer and to an exhaust port according to another embodiment of the present invention;

FIG. 14 is a plan view of a portion of the thermal processing apparatus of FIG. 10 taken along the line A-A of FIG. 10 showing gas flow from orifices of a primary and a secondary injector across a wafer and to an exhaust port according to yet another embodiment of the present invention;

FIG. 15 is a plan view of a portion of the thermal processing apparatus of FIG. 10 taken along the line A-A of FIG. 10 showing gas flow from orifices of a primary and a secondary injector across a wafer and to an exhaust port according to still another embodiment of the present invention;

FIG. 16 is a cross-sectional view of a thermal processing apparatus having an alternative up-flow injector system according to an embodiment of the present invention;

FIG. 17 is a cross-sectional view of a thermal processing apparatus having an alternative down-flow injector system according to an embodiment of the present invention;

FIG. 18 is flowchart showing an embodiment of a process for thermally processing a batch of wafers according to an embodiment of the present invention whereby each wafer of the batch of wafers is quickly and uniformly heated to the desired temperature; and

FIG. 19 is flowchart showing another embodiment of a process for thermally processing a batch of wafers according to an embodiment of the present invention whereby each wafer of the batch of wafers is quickly and uniformly heated to the desired temperature.

FIG. 20 is a cross-sectional view of a thermal processing apparatus including a cross-flow liner according to one embodiment of the present invention.

FIG. 21 is an external view of a cross-flow stepped liner showing a longitudinal bulging section according to one embodiment of the present invention.

FIG. 22 is an external view of a cross-flow stepped liner showing a plurality of exhaust slots in the liner according to one embodiment of the present invention.

FIG. 23 is a side view of a cross-flow liner in accordance with one embodiment of the present invention FIG. 24 is a top plan view of a cross-flow liner in accordance with one embodiment of the present invention.

FIG. 25 is a partial top plan view of a cross-flow liner in accordance with one embodiment of the present invention.

FIG. 26 is a plan view of a cross-flow liner with a bulging section showing gas flow from orifices that impinges the liner inner wall prior to flowing across a wafer and exiting an exhaust slot according to one embodiment of the present invention.

FIG. 27 is a plan view of a cross-flow liner with a bulging section showing gas flow from orifices that impinges each other prior to flowing across a wafer and exiting an exhaust slot according to one embodiment of the present invention.

FIG. 28 is a plan view of a cross-flow liner with a bulging section showing gas flow from orifices directing to the center of a wafer and exiting an exhaust slot according to one embodiment of the present invention.

FIG. 29 is a graphical representation showing gas flow lines across the surface of a wafer inside a chamber including a cross-flow liner and two injection tubes having injection orifices facing the liner inner wall according to one embodiment of the present invention.

FIG. 30 is a graphical representation showing gas flow lines across the surface of a wafer inside a chamber including a prior art liner and two injection tubes having injection orifices facing the liner inner wall.

FIG. 31 is a graphical representation showing gas flow lines across the surface of a wafer inside a chamber including a cross-flow liner and two injection tubes having injection orifices facing each other according to one embodiment of the present invention.

FIG. 32 is a graphical representation showing gas flow lines across the surface of a wafer inside a chamber including a prior art liner and two injection tubes having injection orifices facing each other.

FIG. 33 is a graphical representation showing gas flow lines across the surface of a wafer inside a chamber including a cross-flow liner and two injection tubes having injection orifices facing the center of a wafer according to one embodiment of the present invention.

FIG. 34 is a graphical representation showing gas flow lines across the surface of a wafer inside a chamber including a prior art liner and two injection tubes having injection orifices facing to the center of a wafer.

FIG. 35 is a side view of a cross-flow liner showing a plurality of slots in the liner wall in accordance with one embodiment of the present invention.

FIG. 36 is a cross-sectional view of a cross-flow liner showing a heat shield in accordance with one embodiment of the present invention.

FIG. 37 is a cross-sectional view of a cross-flow liner showing a heat shield in detail in accordance with one embodiment of the present invention.

FIG. 38 is a graphic showing an elongated injection tube and a T-tube in a cross-flow liner according to one embodiment of the present invention.

FIG. 39 is a partial plan view of the top plate of a cross-flow liner showing an opening for receiving the elongated injection tube as shown in FIG. 38.

FIG. 40 is CFD demonstration for a thermal processing apparatus including a cross-flow liner and an injection system having injection ports facing the liner inner wall in accordance with one embodiment of the present invention.

FIG. 41 is CFD demonstration for a thermal processing apparatus including a cross-flow liner and an injection system having injection ports facing each other in accordance with one embodiment of the present invention.

FIG. 42 is CFD demonstration for a thermal processing apparatus including a cross-flow liner and an injection system having injection ports facing the center of a substrate in accordance with one embodiment of the present invention.

### DETAILED DESCRIPTION OF THE INVENTION

The present invention is directed to an apparatus and method for processing a relatively small number or mini-batch of one or more work pieces, such as semiconductor substrates or wafers, held in a carrier, such as a cassette or boat, that provides reduced processing cycle times and improved process uniformity.

As used herein the term “mini-batch” means a number of wafers less than the hundreds of wafers found in the typical batch systems, and preferably in the range of from one to about fifty-three semiconductor wafers or wafers, of which from one to fifty are product wafers and the remainder are non-product wafers used for monitoring purposes and as baffle wafers.

By thermal processing it is meant processes that in which the work piece or wafer is heated to a desired temperature which is typically in the range of about 350° C. to 1300° C. Thermal processing of semiconductor wafers can include, for example, heat treating, annealing, diffusion or driving of dopant material, deposition or growth of layers of material, such as chemical vapor deposition or CVD, and etching or removal of material from the wafers.

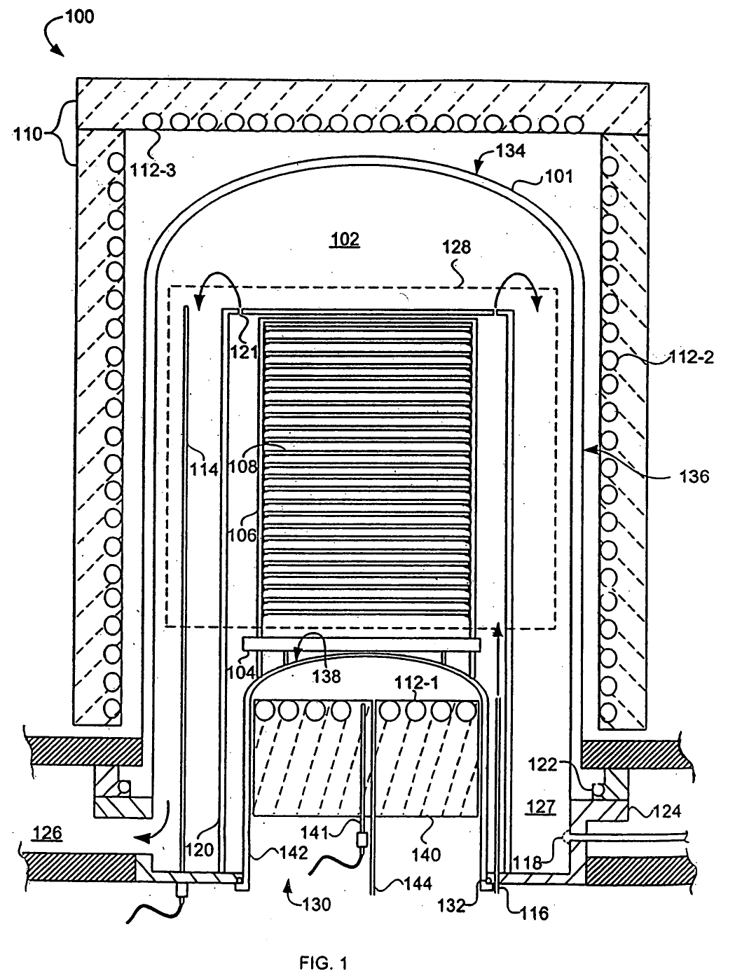

A thermal processing apparatus according to an embodiment will now be described with reference to FIG. 1. For purposes of clarity, many of the details of thermal processing apparatuses that are widely known and are widely known to a person of skill in the art have been omitted. Such detail is described in more detail in, for example, commonly assigned U.S. Pat. No. 4,770,590, which is incorporated herein by reference.

FIG. 1 is a cross-sectional view of an embodiment of a thermal processing apparatus for thermally processing a batch of semiconductor wafers. As shown, the thermal processing apparatus 100, generally includes a vessel 101 that encloses a volume to form a process chamber 102 having a support 104 adapted for receiving a carrier or boat 106 with a batch of wafers 108 held therein, and heat source or furnace 110 having a number of heating elements 112-1, 112-2 and 112-3 (referred to collectively hereinafter as heating elements 112) for raising a temperature of the wafers to the desired temperature for thermal processing. The thermal processing apparatus 100 further includes one or more optical or electrical temperature sensing elements, such as a resistance temperature device (RTD) or thermal couple (T/C), for monitoring the temperature within the process chamber 102 and/or controlling operation of the heating elements 112. In the embodiment shown the temperature sensing element is a profile T/C 114 that has multiple independent temperature sensing nodes or points (not shown) for detecting the temperature at multiple locations within the process chamber 102. The thermal processing apparatus 100 can also include one or more injectors 116 (only one of which is shown) for introducing a fluid, such as a gas or vapor, into the process chamber 102 for processing and/or cooling the wafers 108, and one or more purge ports or vents 118 (only one of which is shown) for introducing a gas to purge the process chamber and/or to cool the wafers. A liner 120 increases the concentration of processing gas or vapor near the wafers 108 in a region or process zone 128 in which the wafers are processed, and reduces contamination of the wafers from flaking or peeling of deposits that can form on interior surfaces of the process chamber 102. Processing gas or vapor exits the process zone through exhaust ports or slots 121 in the chamber liner 120.

Generally, the vessel 101 is sealed by a seal, such as an o-ring 122, to a platform or base-plate 124 to form the process chamber 102, which completely encloses the wafers 108 during thermal processing. The dimensions of the process chamber 102 and the base-plate 124 are selected to provide a rapid evacuation, rapid heating and a rapid backfilling of the process chamber. Advantageously, the vessel 101 and the base-plate 124 are sized to provide a process chamber 102 having dimensions selected to enclose a volume substantially no larger than necessary to accommodate the carrier 106 with the wafers 108 held therein. Preferably, the vessel 101 and the base-plate 124 are sized to provide a process chamber 102 having dimensions of from about 125 to about 150% of that necessary to accommodate the carrier 106 with the wafers 108 held therein, and more preferably, the process chamber has dimensions no larger than about 125% of that necessary to accommodate the carrier and the wafers in order to minimize the chamber volume which aids in pump down and back-fill time required.

Openings for the injectors 116, T/Cs 114 and vents 118 are sealed using seals such as o-rings, VCR®, or CF® fittings. Gases or vapor released or introduced during processing are evacuated through a foreline or exhaust port 126 formed in a wall of the process chamber 102 (not shown) or in a plenum 127 of the base-plate 124, as shown in FIG. 1. The process chamber 102 can be maintained at atmospheric pressure during thermal processing or evacuated to a vacuum as low as 5 millitorr through a pumping system (not shown) including one or more roughing pumps, blowers, hi-vacuum pumps, and roughing, throttle and foreline valves.

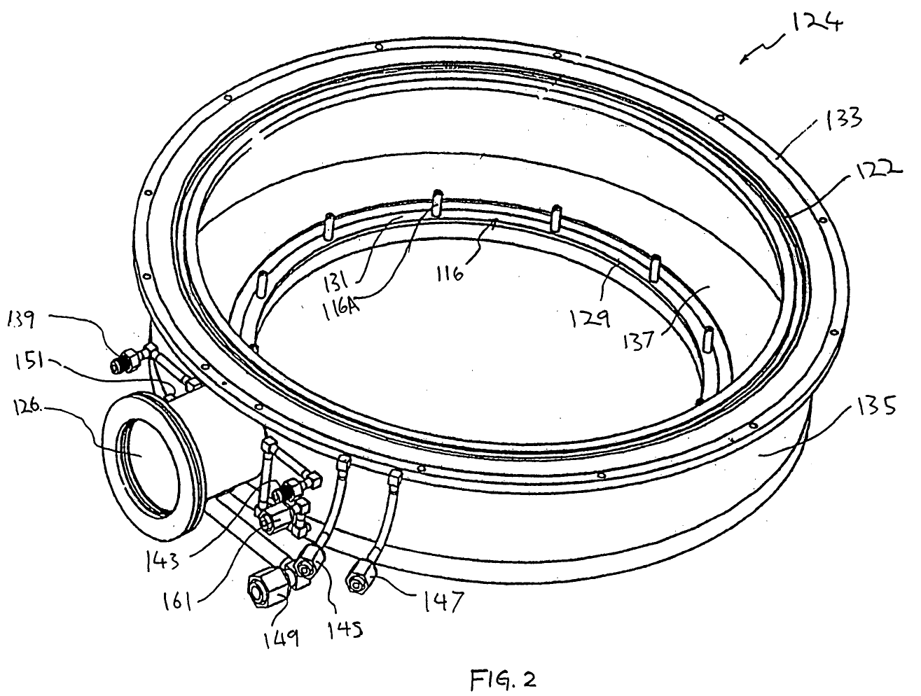

In another embodiment, shown in FIG. 2, the base-plate 124 further includes a substantially annular flow channel 129 adapted to receive and support an injector 116 including a ring 131 from which depend a number of vertical injector tube or injectors 116A. The injectors 116A can be sized and shaped to provide an up-flow, down flow or cross-flow flow pattern, as described below. The ring 131 and injectors 116A are located so as to inject the gas into the process chamber 102 between the boat 106 and the vessel 101. In addition, the injectors 116A are spaced apart around the ring 131 to uniformly introduce process gas or vapor into the process chamber 102, and may, if desired, be used during purging or backfilling to introduce a purge gas into the process chamber. The base-plate 124 is sized in a short cylindrical form with an outwardly extending upper flange 133, a sidewall 135, and an inwardly extending base 137. The upper flange 133 is adapted to receive and support the vessel 101, and contains an o-ring 122 to seal the vessel to the upper flange. The base 137 is adapted to receive and support the liner 120 outside of where the ring 131 of injectors 116 is supported.

Additionally, the base-plate 124 shown in FIG. 2 incorporates various ports including backfill/purge gas inlet ports 139, 143, cooling ports 145,147, provided to circulate cooling fluid in the base-plate 124, and a pressure monitoring port 149 for monitoring pressure within the process chamber 102. Process gas inlet ports 151, 161, introduce a gas from a supply (not shown) to the injectors 116. The backfill/purge ports 139,143, are provided at the sidewall 135 of the base-plate 124 principally to introduce a gas from a vent/purge gas-supply (not shown) to the vents 118. A mass flow controller (not shown) or any other suitable flow controller is placed in line between the gas supplies and the ports 139, 143, 151 and 161 to control the gas flow into the process chamber 102.

The vessel 101 and liner 120 can be made of any metal, ceramic, crystalline or glass material that is capable of withstanding the thermal and mechanical stresses of high temperature and high vacuum operation, and which is resistant to erosion from gases and vapors used or released during processing. Preferably, the vessel 101 and liner 120 are made from an opaque, translucent or transparent quartz glass having a sufficient thickness to withstand the mechanical stresses and that resists deposition of process byproducts, thereby reducing potential contamination of the processing environment. More preferably, the vessel 101 and liner 120 are made from quartz that reduces or eliminates the conduction of heat away from the region or process zone 128 in which the wafers 108 are processed.

The batch of wafers 108 is introduced into the thermal processing apparatus 100 through a load lock or loadport (not shown) and then into the process chamber 102 through an access or opening in the process chamber or base-plate 124 capable of forming a gas fight seal therewith. In the configuration shown in FIG. 1, the process chamber 102 is a vertical reactor and the access utilizes a movable pedestal 130 that is raised during processing to seal with a seal, such as an o-ring 132 on the base-plate 124, and lowered to enable an operator or an automated handling system, such as a boat handling unit (BHU) (not shown), to position the carrier or boat 106 on the support 104 affixed to the pedestal.

The heating elements 112 include elements positioned proximal to a top 134 (elements 112-3), side 136 (elements 112-2) and bottom 138 (elements 112-1) of the process chamber 102. Advantageously, the heating elements 112 surround the wafers to achieve a good view factor of the wafers and thereby provide an isothermal control volume or process zone 128 in the process chamber in which the wafers 108 are processed. The heating elements 112-1 proximal to the bottom 138 of the process chamber 102 can be disposed in or on the pedestal 130. If desired, additional heating elements may be disposed in or on the base plate 124 to supplement heat from the heating elements 112-1.

In the embodiment shown in FIG. 1 the heating elements 112-1 proximal to the bottom of the process chamber preferably are recessed in the movable pedestal 130. The pedestal 130 is made from a thermally and electrically insulating material or insulating block 140 having an electric, resistive heating elements 112-1 embedded therein or affixed thereto. The pedestal 130 further includes one or more feedback sensors or T/Cs 141 used to control the heating elements 112-1. In the configuration shown, the T/Cs 141 are embedded in the center of the insulating block 140.

The side heating elements 112-2 and the top heating elements 112-3 may be disposed in or on an insulating block 110 about the vessel 101. Preferably the side heating elements 112-2 and the top heating elements 112-3 are recessed in the insulating block 110.

The heating elements 112 and the insulating blocks 110 and 140 may be configured in any of a variety of ways and may be made in any of a variety of ways and with any of a variety of materials.

Preferably, to attain desired processing temperatures of up to 1150° C. the heating elements 112-1 proximal to the bottom 138 of the process chamber 102 have a maximum power output of from about 0.1 kW to about 10 kW with a maximum process temperature of at least 1150° C. More preferably, these bottom heating elements 112-1 have a power output of at least about 3.8 kW with a maximum process temperature of at least 950° C. In one embodiment, the side heating elements 112-2 are functionally divided into multiple zones, including a lower zone nearest the pedestal 130 and upper zone, each of which are capable of being operated independently at different power levels and duty cycles from each other and from the top heating elements 112-3 and bottom heating elements 112-1.

The heating elements 112 are controlled in any suitable manner, either by using a control technique of a type well known in the art.

Contamination from the insulating block 140 and bottom heating elements 112-1 is reduced if not eliminated by housing the heating element and insulation block in an inverted quartz crucible 142, which serves as a barrier between the heating element and insulation block and the process chamber 102. The crucible 142 is also sealed against the loadport and BHU environment to further reduce or eliminate contamination of the processing environment. Generally, the interior of the crucible 142 is at standard atmospheric pressure, so that the crucible 142 should be strong enough to withstand a pressure differential between the process chamber 102 and the pedestal 130 across the crucible 142 of as much as 1 atmosphere.

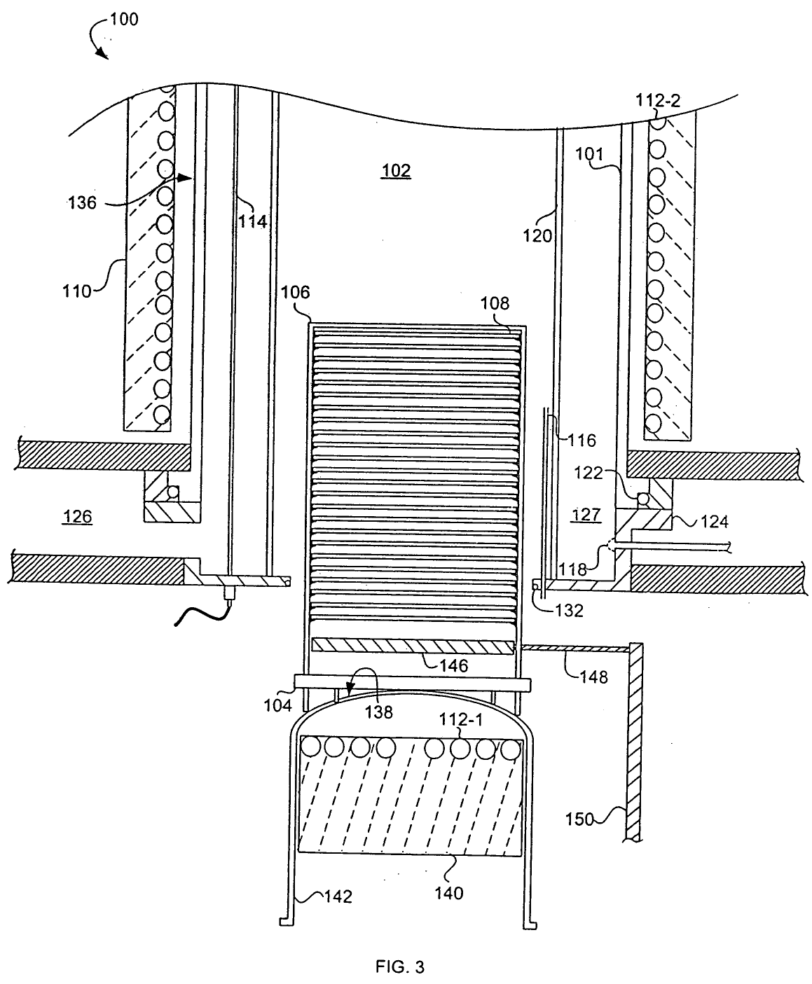

While the wafers 108 are being loaded or unloaded, that is while the pedestal 130 is in the lowered position (FIG. 3), the bottom heating elements 112-1 are powered to maintain an idle temperature lower than the desired processing temperature. For example, for a process having a desired processing temperature for the bottom heating elements of 950° C., the idle temperature can be from 50-150°. The idle temperature can be set higher for certain processes, such as those having a higher desired processing temperature and/or higher desired ramp up rate, or to reduce thermal cycling effects on the bottom heating elements 112-1, thereby extending element life.

In order to further reduce preprocessing time, that is the time required to prepare the thermal processing apparatus 100 for processing, the bottom heating elements 112-1 can be ramped to at or below the desired process temperature during the push or load, that is while the pedestal 130 with a boat 106 of wafers 108 positioned thereon is being raised. However, to minimize thermal stresses on the wafers 108 and components of the thermal processing apparatus 100 it is preferred to have the bottom heating elements 112-1 reach the desired process temperature at the same time as the heating elements 112-3 and 112-2 located proximal to respectively the top 134 and side 136 of the process chamber 102. Thus, for some processes, such as those requiring higher desired process temperatures, the temperature of the bottom heating elements 112-1 can begin being ramped up before the pedestal 130 begins being raised, while the last of the wafers 108 in a batch are being loaded.

Similarly, it will be appreciated that after processing and during the pull or unload cycle, that is while the pedestal 128 is being lowered, power to the bottom heating elements 112-1 can be reduce or removed completely to begin ramping down the pedestal 130 to the idle temperature, in preparation for cooling of the wafers 108 and unloading by the BHU.

To assist in cooling the pedestal 130 to a pull temperature prior to the pull or unload cycle, a purge line for air or an inert purge gas, such as nitrogen, is installed through the insulating block 140. Preferably, nitrogen is injected through a passage 144 through the center of the insulating block 140 and allowed to flow out between the top of the insulating block 140 and the interior of the crucible 142 to a perimeter thereof. The hot nitrogen is then exhausted to the environment either through High Efficiency Particulate Air (HEPA) filter (not shown) or to a facility exhaust (not shown). This center injection configuration facilitates the faster cooling of the center of the wafers 108, and therefore is ideal to minimize the center/edge temperature differential of the bottom wafer or wafers, which could otherwise result in damage due to slip-dislocation of the crystal lattice structure.

As noted above, to increase or extend the life of bottom heating element 112-1 the idle temperature can be set higher, closer to the desired processing temperature to reduce the effects of thermal cycling. In addition, it is also desirable to periodically bake out the heating elements 112-1 in an oxygen rich environment to promote,the formation of a protective oxide surface coat. For example, where the resistive heating elements are formed from an Aluminum containing alloy, such as Kanthal®, baking out the heating elements 112-1 in an oxygen rich environment promotes an alumna oxide surface growth. Thus, the insulating block 140 can further include an oxygen line (not shown) to promote the formation of the protective oxide surface coat during bake out of the heating elements 112-1. Alternatively, oxygen for bake out can be introduced through the purge line used during processing to supply cooling nitrogen via a three-way valve.

FIG. 3 is a cross-sectional view of a portion of a thermal processing apparatus 100. FIG. 3 shows the thermal processing apparatus 100 while the wafers 108 are being loaded or unloaded, that is while the pedestal 130 is in the lowered position. In this mode of operation, the thermal processing apparatus 100 further includes a thermal shield 146 that can be rotated or slid into place above the pedestal 130 and the lower wafer 108 in the boat 106. To improve the performance of the thermal shield 146, generally the thermal shield is reflective on the side facing the heating elements 112-1 and absorptive on the side facing the wafers 108. Purposes of the thermal shield 146 include increasing the rate of cooling of the wafers 108 lower down in the boat 106, and assisting in maintaining the idle temperature of the pedestal 130 and bottom heating elements 112-1 to decrease the time required to ramp up the process chamber 102 to the desired processing temperature. An embodiment of a thermal processing apparatus having a thermal shield will now be described in further detail with reference to FIGS. 3 through 6.

FIG. 3 also shows an embodiment of a thermal processing apparatus 100 having pedestal heating elements 112-1 and a thermal shield 146. In the embodiment shown, the thermal shield 146 is attached via arm 148 to a rotable shaft 150 that is turned by an electric, pneumatic or hydraulic actuator to rotate the thermal shield 146 into a first position between the heated pedestal 130 and the lowest of the wafers 108 in the boat 106 during the pull or unload cycle, and removed or rotated to a second position not between the pedestal and the wafers during at least a final portion or end of the push or load cycle, just before the bottom of the boat 106 enters into the chamber 102. Preferably, the rotable shaft 150 is mounted on or affixed to the mechanism (not shown) used for raising and lowering the pedestal 130, thereby enabling the thermal shield 146 to be rotated into position as soon as the top of the pedestal has cleared the process chamber 102. Having the shield 146 in place during the load cycle enables the heating elements 112-1 to be heated to a desired temperature more rapidly than would otherwise be possible. Similarly, during unload cycle the shield 146 helps in cooling the wafers, particularly those closer to the pedestal, by reflect the heat radiating from the pedestal heating elements 112-1.

Alternatively, the rotable shaft 150 can be a mounted on or affixed to another part of the thermal processing apparatus 100 and adapted to move axially in synchronization with the pedestal 130, or to rotate the thermal shield 146 into position only when the pedestal is fully lowered.

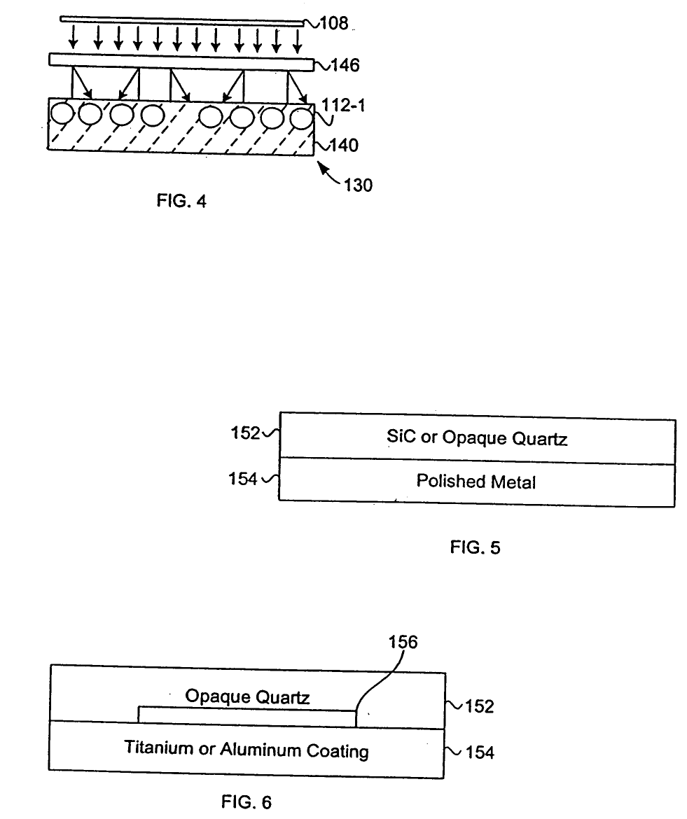

FIG. 4 is a diagrammatic illustration of the pedestal heating elements 112-1 and thermal shield 146 of FIG. 3 illustrating the reflection of thermal energy or heat radiating from the bottom heating elements back to the pedestal 130 and the absorption of thermal energy or heat radiating from the lower wafer 108 in the batch or stack of wafers. It has been determined that the desired characteristics, high reflectivity and high absorptivity, can be obtained using a number of different materials, such as metals, ceramic, glass or polymeric coatings, either individually or in combination. By way of example the following table list various suitable materials and corresponding parameters.

TABLE I

| Material | Absorptivity | Reflectivity |
|---|---|---|
| Stainless Steel | 0.2 | 0.8 |
| Opaque Quartz | 0.5 | 0.5 |
| Polished Aluminum | 0.03 | 0.97 |
| Silicon Carbide | 0.9 | 0.1 |

According to one embodiment the thermal shield 146 can be made from a single material such as silicon-carbide (SiC), opaque quartz or stainless steel which has been polished on one side and scuffed, abraded or roughened on the other. Roughening a surface of the thermal shield 146 can significantly change its heat transfer properties, particularly its reflectivity.

In another embodiment, the thermal shield 146 can be made from two different layers of material. FIG. 5 is a diagrammatic illustration of a thermal shield 146 having a top layer 152 of material such as SiC or opaque quartz, with a high absorptivity and a lower layer 154 of material or metal, such as polished stainless steel or polished aluminum, with a high reflectivity. Although shown as having approximately equal thicknesses, it will be appreciated that either the top layer 152 or the lower layer 154 can have a relatively greater thickness depending on specific requirements for the thermal shield 146, such as minimizing thermal stresses between the layers due to differences in coefficients of thermal expansion. For example, in certain embodiments the lower layer 154 can be an extremely thin layer or film of polished metal deposited, formed or plated on a quartz plate that forms the top layer 152. The materials can be integrally formed or interlocking, or joined by conventional means such as bonding or fasteners.

In yet another embodiment, the thermal shield 146 further includes an internal cooling channel 156 to further insulate the wafers 108 from the bottom heating elements 112-1. In one version of this embodiment, shown in FIG. 6, the cooling channel 156 is formed between two different layers 152 and 154 of material. For example, the cooling channel 156 can be formed by milling or any other suitable technique in a highly absorptive opaque quartz layer 152, and be covered by a metal layer 154 or coating such as a Titanium or Aluminum coating. Alternatively, the cooling channel 156 can be formed in the metal layer 154 or both the metal layer and the quartz layer 152.

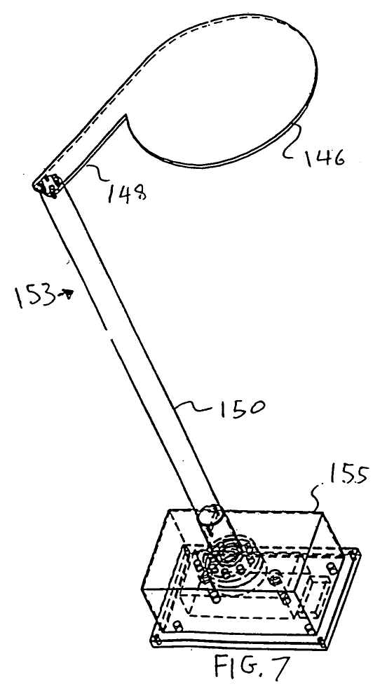

FIG. 7 is a perspective view of an embodiment of a thermal shield assembly 153 including the thermal shield 146, arm 148, rotable shaft 150 and an actuator 155.

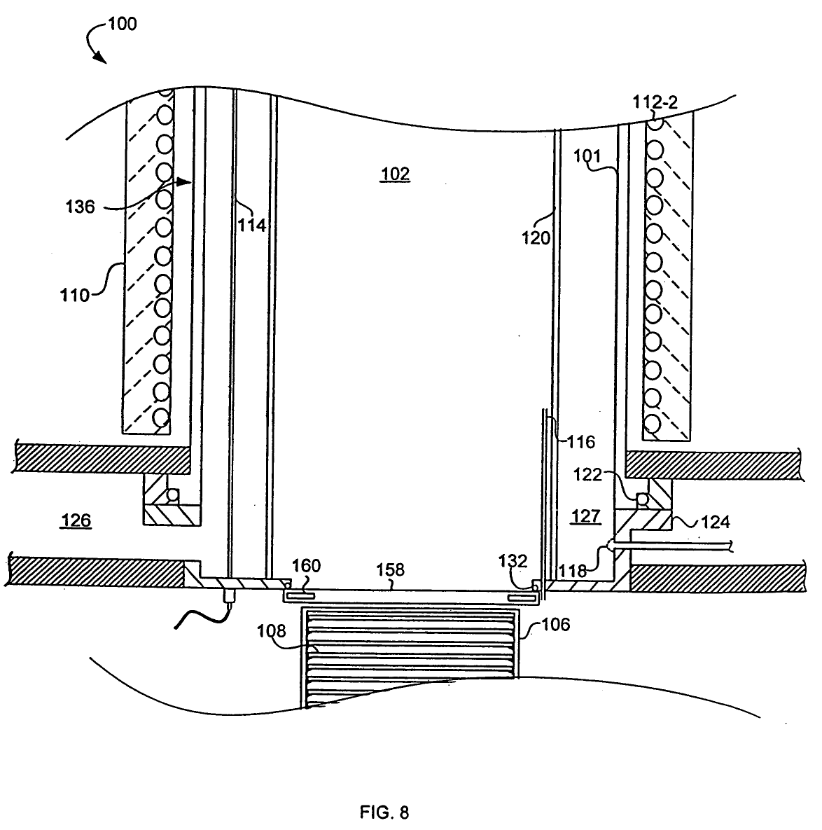

As shown in FIG. 8, the thermal processing apparatus 100 further includes a shutter 158 that can be rotated or slid or otherwise moved into place above the boat 106 to isolate the process chamber 102 from the outside or load port environment when the pedestal 130 is in the fully lowered position. For example, the shutter 158 can be slid into place above the carrier 106 when the pedestal 130 is in a lowered position, and raised to isolate the process chamber 102. Alternatively, the shutter 158 can be rotated or swung into place above the carrier 106 when the pedestal 130 is in a lowered position, and subsequently raised to isolate the process chamber 102. Optionally, the shutter 158 may be rotated about or relative to threaded screw or rod to simultaneously raise the shutter to isolate the process chamber 102 as it is swung into place above the carrier 106.

For a process chamber 102 that is normally operated under vacuum, such as in a CVD system, the shutter 158 could form a vacuum seal against the base-plate 124 to allow the process chamber 102 to be pumped down to the process pressure or vacuum. For example, it may be desirable to pump down the process chamber 102 between sequential batches of wafers to reduce or eliminate the potential for contaminating the process environment. Forming a vacuum seal is preferably done with a large diameter seal, such as an o-ring, and thus the shutter 158 can desirably include a number of water channels 160 to cool the seal. In the embodiment shown in FIG. 8 the shutter 158 seals with the same o-ring 132 used to seal with the crucible 142 when the pedestal 130 is in the raised position.

For a thermal processing apparatus 130 in which the process chamber 102 is normally operated at atmospheric pressure, the shutter 158 is simply an insulating plug designed to reduce heat loss from the bottom of the process chamber. One embodiment for accomplishing this involves the use of an opaque quartz plate, which may or may not further include a number of cooling channels underneath or internal thereto.

When the pedestal 130 is in the fully lowered position, the shutter 158 is moved into position below the process chamber 102 and then raised to isolate the process chamber by one or more electric, hydraulic or pneumatic actuators (not shown). Preferably, the actuators are pneumatic actuators using from about 15 to 60 pounds per square inch gauge (PSIG) air, which is commonly available on thermal processing apparatus 100 for operation of pneumatic valves. For example, in one version of this embodiment the shutter 158 can comprise a plate having a number of wheels attached via short arms or cantilevers to two sides thereof. In operation, the plate or shutter 158 is rolled into position beneath the process chamber 102 on two parallel guide rails. Stops on the guide rails then cause the cantilevers to pivot translating the motion of the shutter 158 into an upward direction to seal the process chamber 102.

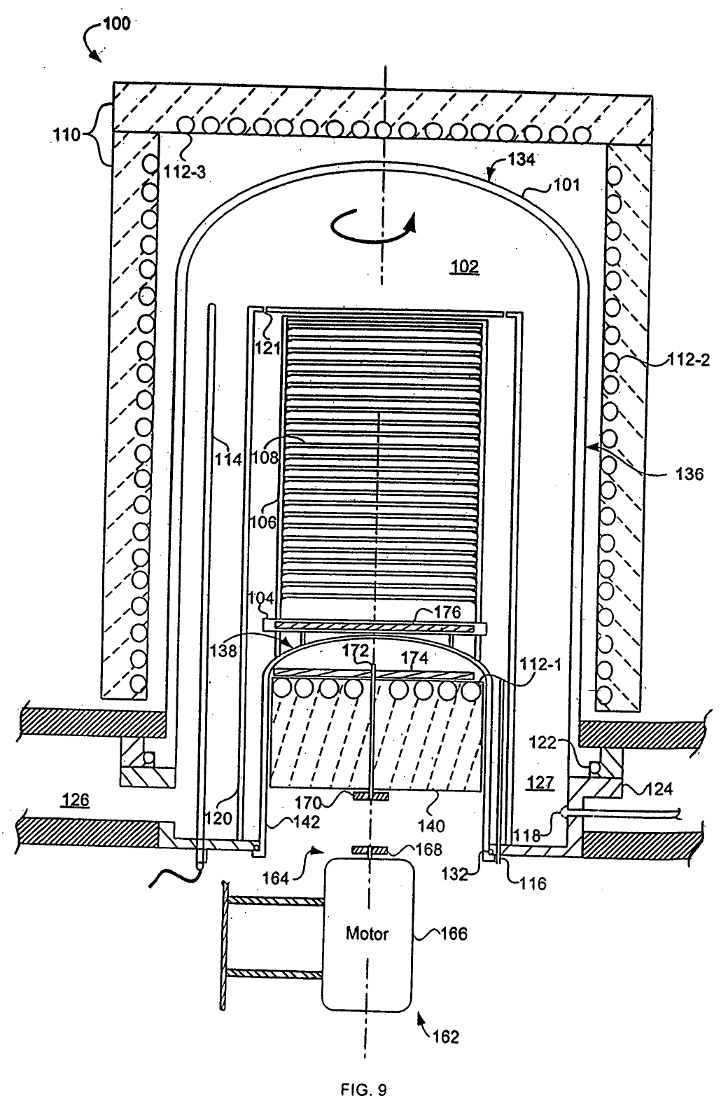

As shown in FIG. 9, the thermal processing apparatus 100 further includes a magnetically coupled wafer rotation system 162 that rotates the support 104 and the boat 106 along with the wafers 108 supported thereon during processing. Rotating the wafers 108 during processing improves within wafer (WIW) uniformity by averaging out any non-uniformities in the heating elements 112 and in process gas flows to create a uniform on-wafer temperature and species reaction profile. Generally, the wafer rotation system 162 is capable of rotated the wafers 108 at a speed of from about 0.1 to about 10 revolutions per minute (RPM).

The wafer rotation system 162 includes a drive assembly or rotating mechanism 164 having a rotating motor 166, such as an electric or pnetumatic motor, and a magnet 168 encased in a chemically resistive container, such as annealed polytetrafluoroethylene or stainless steel. A steel ring 170 located just below the insulating block 140 of the pedestal 130, and a drive shaft 172 with the insulating block transfer the rotational energy to another magnet 174 located above the insulating block in a top portion of the pedestal. The steel ring 170, drive shaft 172 and second magnet 174 are also encased in a chemically resistive container compound. The magnet 174 located in the side of the pedestal 130 magnetically couples through the crucible 142 with a steel ring or magnet 176 embedded in or affixed to the support 104 in the process-chamber 102.

Magnetically coupling the rotating mechanism 164 through the pedestal 130 eliminates the need for locating it within the processing environment or for having a mechanical feedthrough, thereby eliminating a potential source of leaks and contamination. Furthermore, locating rotating mechanism 164 outside and at some distance from the processing minimizes the maximum temperature of to which it is exposed, thereby increasing the reliability and operating life of the wafer rotation system 162.

In addition to the above, the wafer rotation system 162 can further include one or more sensors (not shown) to ensure proper boat 106 position and proper magnetic coupling between the steel ring or magnet 176 in the process chamber 102 and the magnet 174 in the pedestal 130. A sensor which determines the relative position of the boat 106, or boat position verification sensor, is particularly useful. In one embodiment, the boat position verification sensor includes a sensor protrusion (not shown) on the boat 106 and an optical or laser sensor located below the base-plate 124. In operation, after the wafers 108 have been processed and the pedestal 130 is lowered about 3 inches below the base-plate 124. There, the wafer rotation system 162 is commanded to turn the boat 106 until the boat sensor protrusion can be seen. Then, the wafer rotation system 162 is operated to align the boat so that the wafers 108 can be unloaded. After this is done, the boat is lowered to the load/unload height. After the initial check, it is only capable of verifying the boat location from the flag sensor.

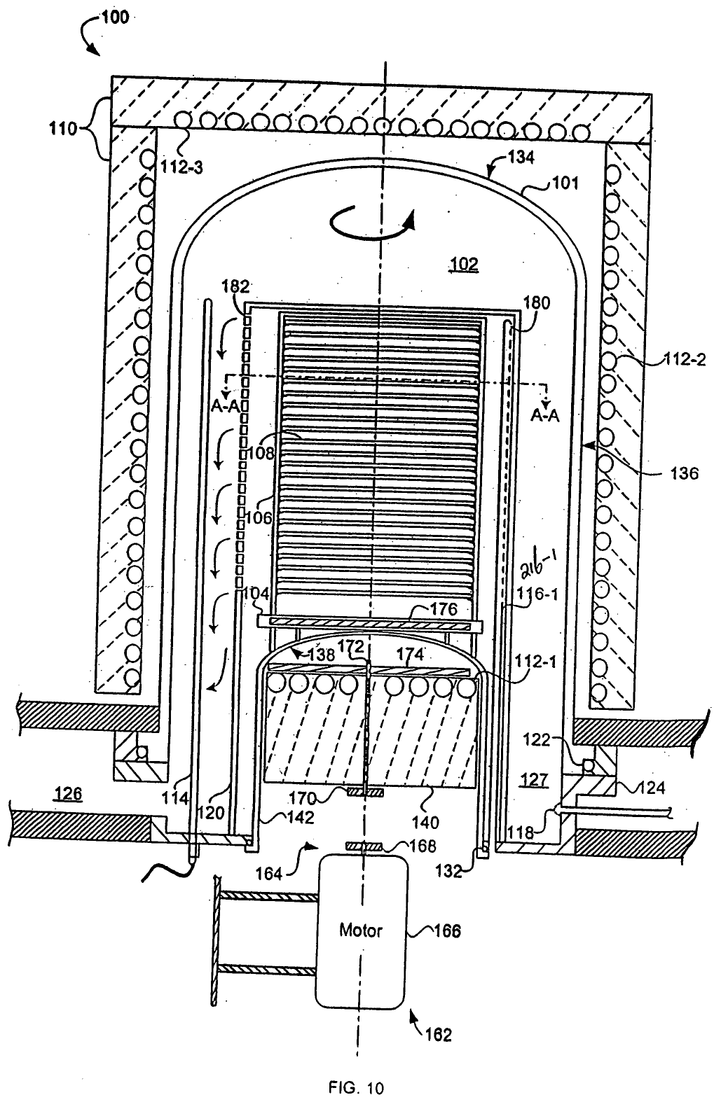

As shown in FIG. 10, improved injectors 216 are preferably used in the thermal processing apparatus 100. The injectors 216 are distributive or cross(X)-flow injectors 216-1 in which process gas or vapor is introduced through injector openings or orifices 180 on one side of the wafers 108 and boat 106 and caused to flow across the surfaces of the wafers in a laminar flow to exit exhaust ports or slots 182 in the chamber line 120 on opposite the side. X-flow injectors 116-1 improve wafer 108 to wafer uniformity within a batch of wafers 108 by providing an improved distribution of process gas or vapor over earlier up-flow or down flow configurations.

Additionally, X-flow injectors 216 can serve other purposes, including the injection of gases for cool-down (e.g., helium, nitrogen, hydrogen) for forced convective cooling between the wafers 108. Use of X-flow injectors 216 results in a more uniform cooling between wafers 108 whether disposed at the bottom or top of the stack or batch and those wafers that are disposed in the middle, as compared with earlier up-flow or down flow configurations. Preferably, the injector 216 orifices 180 are sized, shaped and position to provide a spray pattern that promotes forced convective cooling between the wafers 108 in a manner that does not create a large temperature gradient across the wafer.

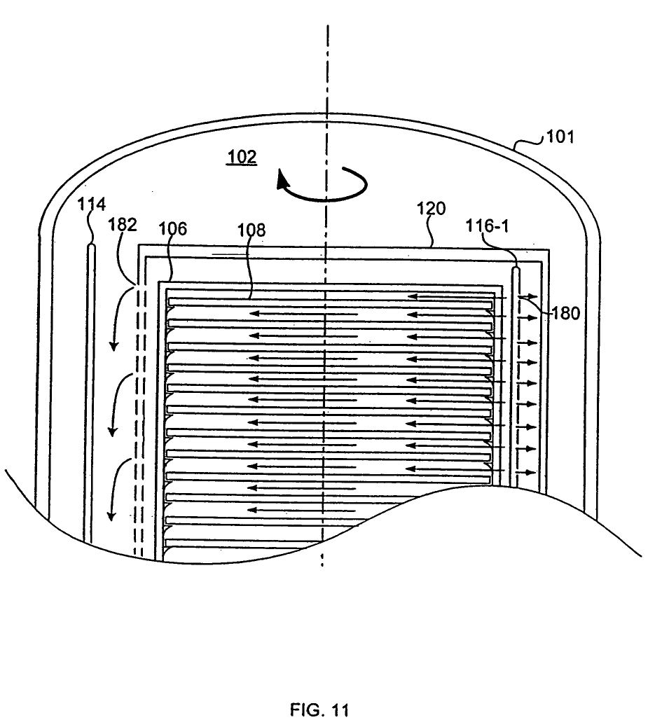

FIG. 11 is a cross-sectional side view of a portion of the thermal processing apparatus 100 of FIG. 10 showing illustrative portions of the injector orifices 180 in relation to the chamber liner 120 and the exhaust slots 182 in relation to the wafers 108.

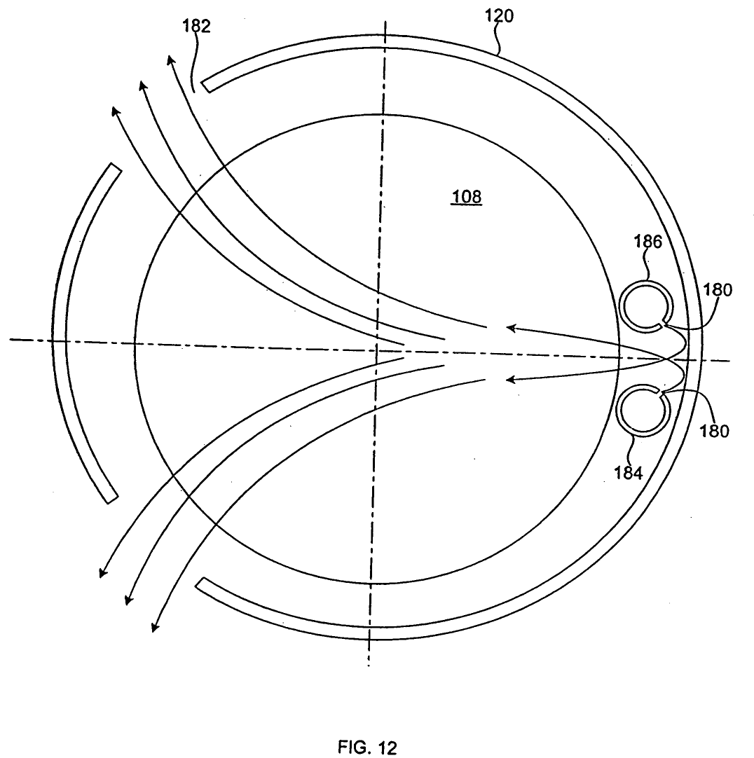

FIG. 12 is a plan view of a portion of the thermal processing apparatus 100 of FIG. 10 taken along the line A-A of FIG. 10 showing laminar gas flow from the orifices 180-1 and 180-2 of primary and secondary injectors 184, 186, across an illustrative one of the wafers 108 and to exhaust slots 182-1 and 182-2 according to one embodiment. It should be noted that the position of the exhaust slot 182 as shown in FIG. 10 have been shifted from the position of exhaust slots 182-1 and 182-2 shown in FIG. 12 to allow illustration of the exhaust slot and injector 116-1 in a single a cross-sectional view of a thermal processing apparatus. It should also be noted that the dimensions of the injectors 184, 186, and the exhaust slots 182-1 and 182-2 relative to the wafer 108 and the chamber liner 120 have been exaggerated to more clearly illustrate the gas flow from the injectors to the exhaust slots.

Also as shown in FIG. 12, the process gas or vapor is initially directed away from the wafers 108 and toward the liner 120 to promote mixing of the process gas or vapor before it reaches the wafers. This configuration of orifices 180-1 and 180-2 is particularly useful for processes or recipes in which different reactants are introduced from each of the primary and secondary injectors 184, 186, for example to form a multi-component film-or layer.

FIG. 13 is another plan view of a portion of the thermal processing apparatus 100 of FIG. 10 taken along the line A-A of FIG. 10 showing an alternative gas flow path from the orifices 180 of the primary and secondary injector 184, 186, across an illustrative on of the wafer 108 and to the exhaust slots 182 according to another embodiment.

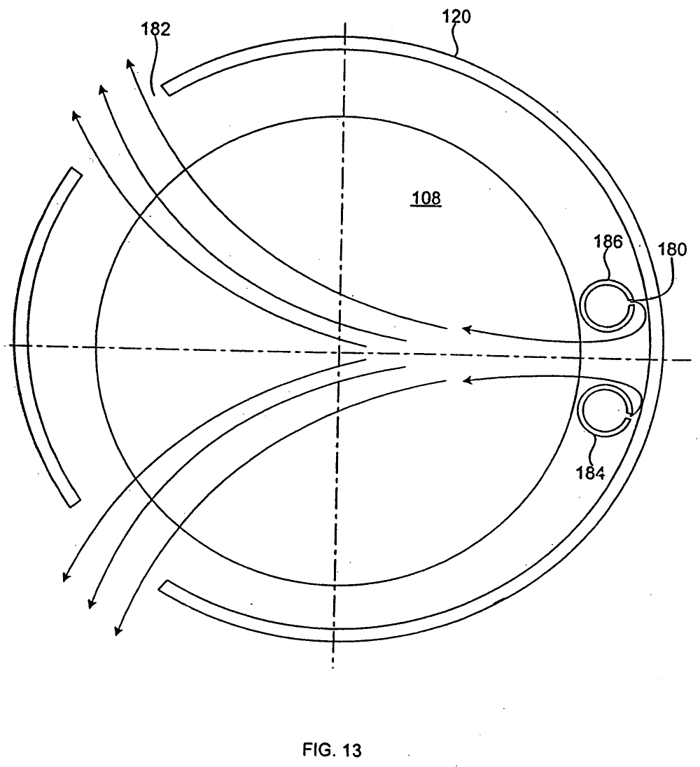

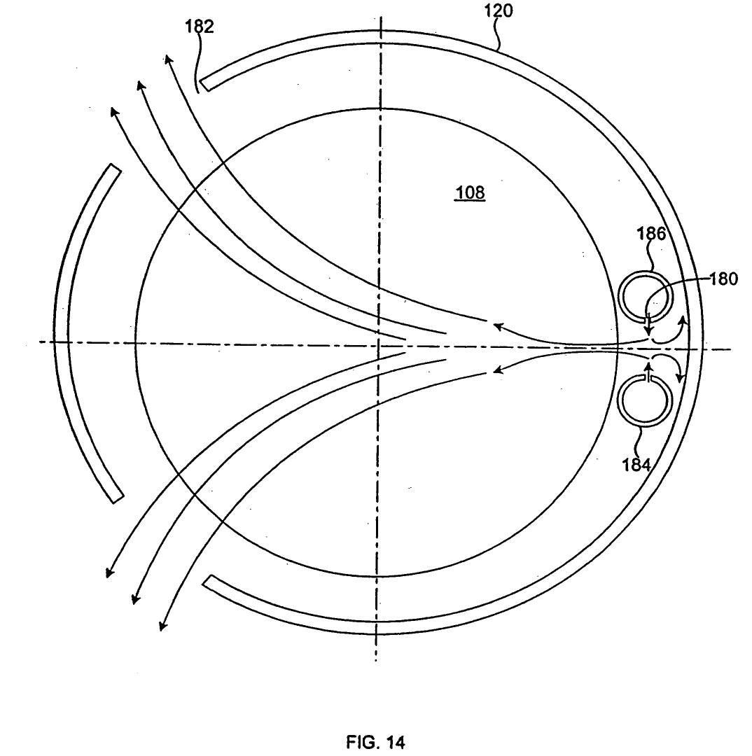

FIG. 14 is another plan view of a portion of the thermal processing apparatus 100 of FIG. 10 taken along the line A-A of FIG. 10 showing an alternative gas flow path from the orifices 180 of the primary and secondary injector 184, 186, across an illustrative on of the wafer 108 and to the exhaust slots 182 according to yet another embodiment.

FIG. 15 is another plan view of a portion of the thermal processing apparatus 100 of FIG. 10 taken along the line A-A of FIG. 10 showing an alternative gas flow path from the orifices 180 of the primary and secondary injector 184, 186, across an illustrative on of the wafer 108 and to the exhaust slots 182 according to still another embodiment.

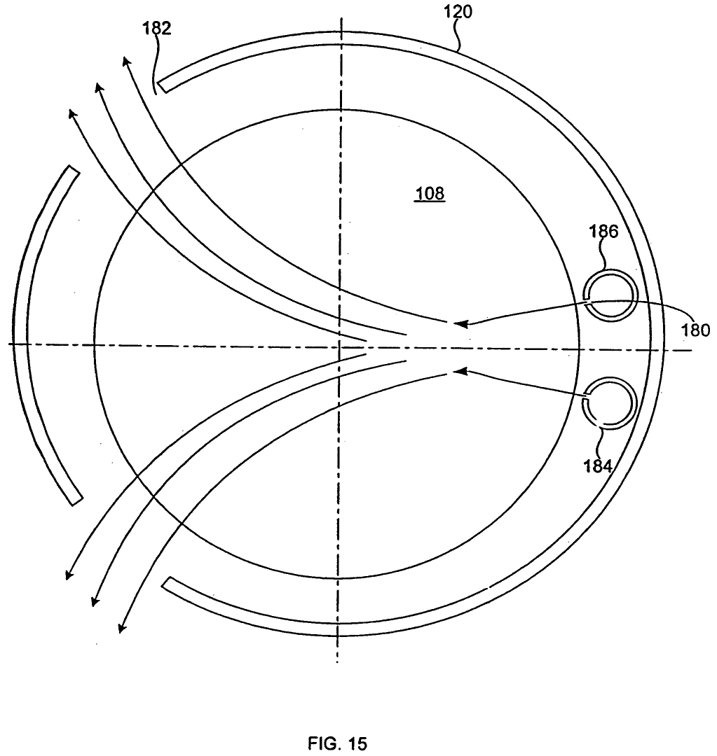

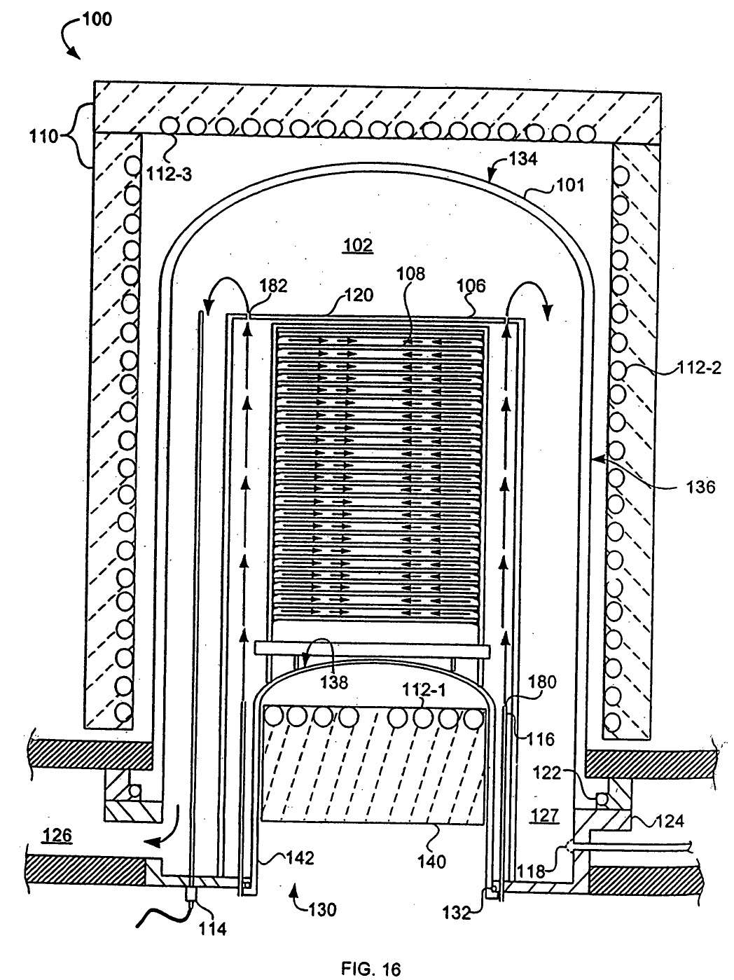

FIG. 16 is a cross-sectional view of a thermal processing apparatus 100 having two or more up-flow injectors 116-1 and 116-2 according to an alternative embodiment. In this embodiment, process gas or vapor admitted from the process injectors 116-1 and 116-2 having respective outlet orifices low in the process chamber 102 flows up and across the wafers 108, and spent gases exit exhaust slots 182 in the top of the liner 120. An up-flow injector system is also shown in FIG. 1.

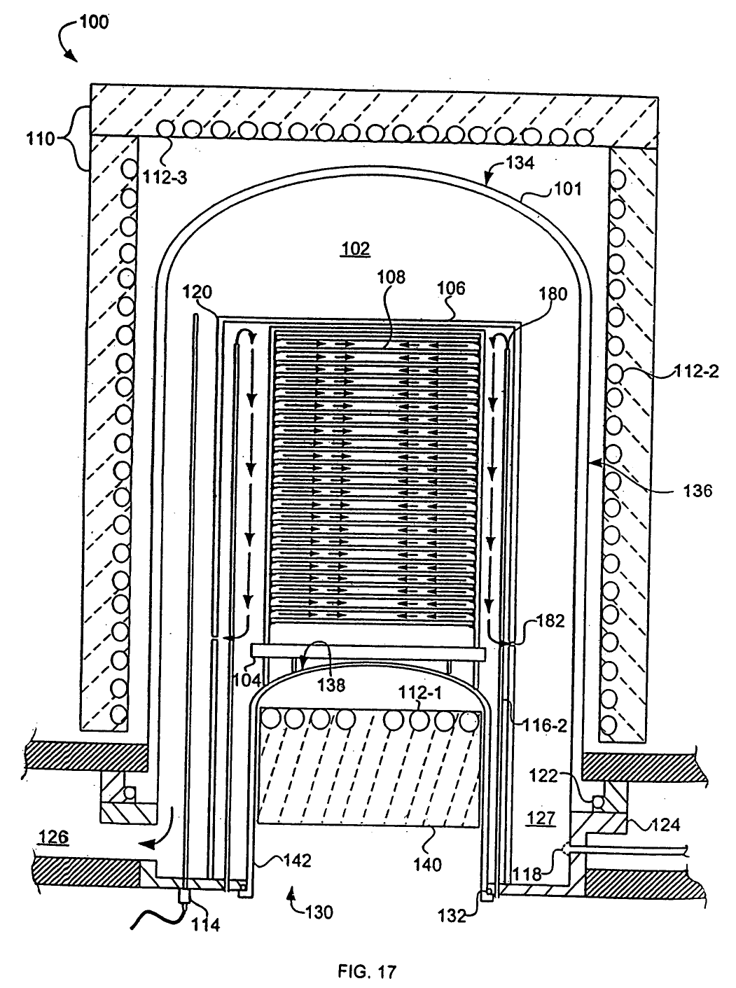

FIG. 17 is a cross-sectional view of a thermal processing apparatus 100 having a down-flow injector system according to an alternative embodiment. In this embodiment, process gas or vapor admitted from process injectors 116-1 and 116-2 having respective orifices high in the process chamber 102 flows down and across the wafers 108, and spent gases exit exhaust slots 182 in the lower portion of the liner 120.

Advantageously, the injectors 116, 216, and/or the liner 120 can be quickly and easily replaced or swapped with other injectors and liners having different points for the injection and exhausting of the process gas from the process zone 128. It will be appreciated by those skilled in the art that the embodiment of the x-flow injector 216 shown in FIG. 10 adds a degree of process flexibility by enabling the flow pattern within the process chamber 102 to be quickly and easily changed from a cross-flow configuration, as shown in FIG. 10, to an up-flow configuration, as shown in FIGS. 1 and 16, or a down-flow configuration, as shown in FIG. 17. This can be accomplished through the use of easily installable injector assemblies 216 and liners 120 to convert the flow geometry from cross-flow to an up-flow or down-flow.

The injectors 116, 216,and the liner 120 can be separate components, or the injector can be integrally formed with liner as a single piece. The latter embodiment is particular useful in applications where it is desirable to frequently change the process chamber 102 configuration.

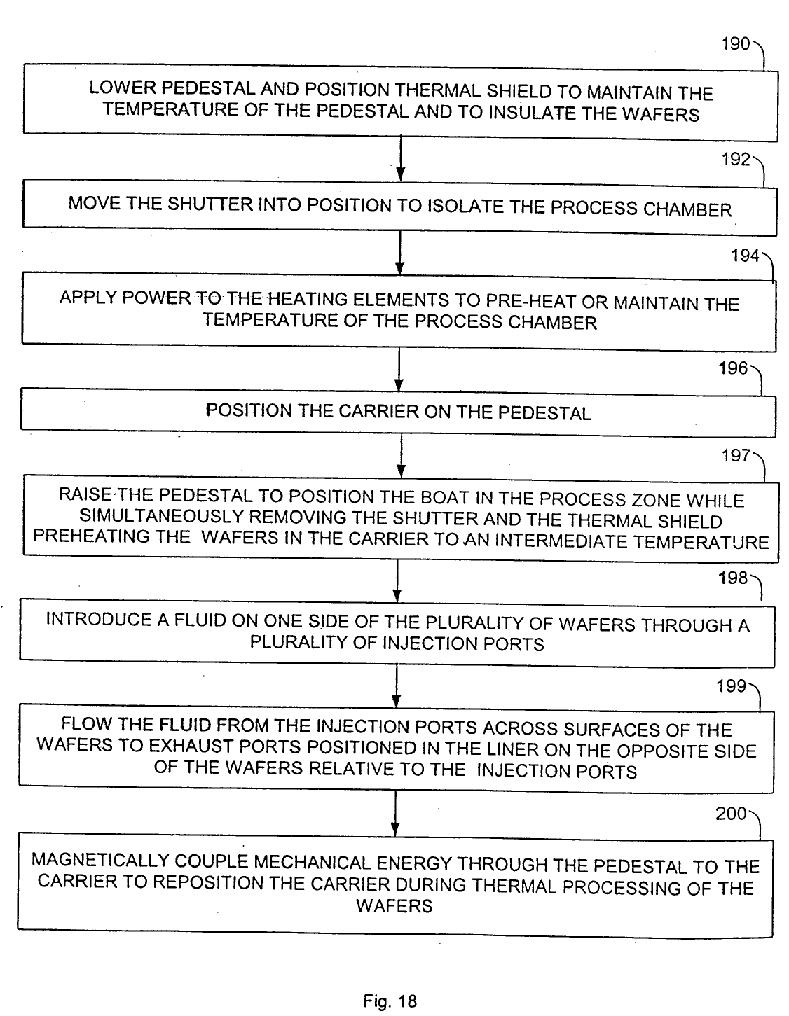

An illustrative method or process for operating the thermal processing apparatus 100 is described with reference to FIG. 18. FIG. 18 is a flowchart showing steps of a method for thermally processing a batch of wafers 108 wherein each wafer of the batch of wafers is quickly and uniformly heated to the desired temperature. In the method, the pedestal 130 is lowered, and the thermal shield 142 is moved into a position while the pedestal 130 is lowered to reflect heat from the bottom heating element 112-1 back to the pedestal 130 to maintain the temperature thereof, and to insulate the finished wafers 108 (step 190). Optionally, the shutter 158 is moved into position to seal or isolate the process chamber 102 (step 192), and power is applied to the heating elements 112-2, 112-3, to begin pre-heating the process chamber 102 to or maintain at an intermediate or idling temperature (step 194). A carrier or boat 106 loaded with new wafers 108 is positioned on the pedestal 130 (step 196). The pedestal 130 is raised to position the boat in the process zone 128, while simultaneously removing the shutter 158, the thermal shield 142, and ramping-up the bottom heating element 112-1 to preheat the wafers to an intermediate temperature (step 197). Preferably, the thermal shield 142 is removed just before the boat 106 is positioned in the process zone 128. A fluid, such as a process gas or vapor, is introduced on one side of the of wafers 108 through a plurality of injection ports 180 (step 198). The fluid flows from the injection ports 180 across surfaces of the wafers 108 to exhaust ports 182 positioned in the liner 120 on the opposite side of the wafers relative to the injection ports (step199). Optionally, the boat 106 can be rotated within the process zone 128 during thermal processing of the batch of wafers 108 to further enhance uniformity of the thermal processing, by magnetically coupling mechanical energy through the pedestal 130 to the carrier or boat 106 to reposition it during thermal processing of the wafers (step 200).

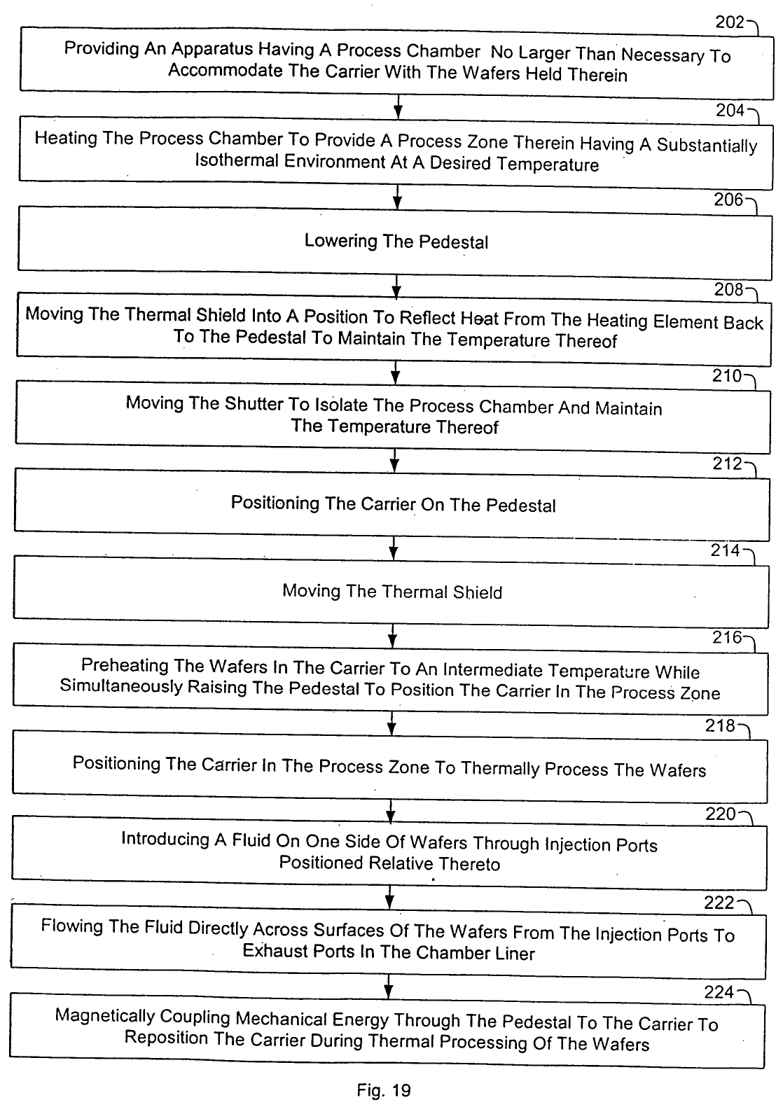

A method or process for a thermal processing apparatus 100 according to another embodiment will now be described with reference to FIG. 19. FIG. 19 is a flowchart showing steps of an embodiment of a method for thermally processing a batch of wafers 108 in a carrier. In the method, an apparatus 100 is provided having a process chamber 102 with dimensions and a volume not substantially larger than necessary (guard heaters absent) to accommodate the carrier 106 with the wafers 108 held therein. The pedestal 130 is lowered, and the boat 106 with the wafers 108 held therein positioned thereon (step 202). The pedestal 130 is raised to insert the boat in the process chamber 102, while simultaneously preheating the wafers 108 to an intermediate temperature (step 204). Power is applied to the heating elements 112-1, 112-2, 112-3, each disposed proximate to at least one of the top wall 134, the side wall 136 and the bottom wall 138 of the process chamber 102 to begin heating the process chamber (step 206). Optionally, power to at least one of the heating elements is adjusted independently to provide a substantially isothermal environment at a desired temperature in a process zone 128 in the process chamber 102 (step 208). When the wafers 108 have been thermally processed, and while maintaining the desired temperature in the process zone 128, the pedestal 130 is lowered, and the thermal shield 142 is moved into position to insulate the finished wafers 108 and to reflect heat from the bottom heating element 112-1 back to the pedestal 130 to maintain the temperature thereof (step 210). Also, optionally, the shutter 158 is moved into position to seal or isolate the process chamber 102, and power applied to the heating elements 112-2, 112-3, to maintain the temperature of the process chamber (step 212). The boat 106 is then removed from the pedestal 130 (step 214), and another boat loaded with a new batch of wafers to be processed positioned on the pedestal (step 216). The shutter 158 is repositioned or removed (step 218), and the thermal shield withdrawn or repositioned to preheat the wafers 108 in the boat 106 to an intermediate temperature while simultaneously raising the pedestal 130 to insert the boat into the process chamber 102 to thermally process the new batch of wafers (step 220).

It has been determined that the thermal processing apparatus 100 provided and operated as described above, reduces the processing or cycle time by about 75% over conventional systems. For example, a conventional large batch thermal processing apparatus may process 100 product wafers in about 232 minutes, including pre-processing and post-processing time. The inventive thermal processing apparatus 100 performs the same processing on a mini-batch of 25 product wafers 108 in about 58 minutes.

Referring to FIGS. 2042, a cross-flow (X-flow) liner in accordance with one embodiment of the present invention will be now described.

Stepped liners are typically used in traditional up-flow vertical furnaces to increase process gas velocities and diffusion control. They are also used as an aid to improve within-wafer uniformity. Unfortunately, stepped liners do not correct down-the-stack-depletion problems, which occur due to single injection point of reactant gases forcing all injected gases to flow past all surfaces down the stack. In prior art vertical cross-flow furnaces, the down-the-stack-depletion problem is solved. However, a flow path of least resistance may be created in the gap region between the wafer carrier and the liner inner wall instead of between the wafers. This least resistance path may cause vortices or stagnation which are detrimental to manufacturing processes. Vortices and stagnation in a furnace may create across wafer non-uniformity problems for some process chemistries.

The present invention provides a cross-flow liner that significantly improves the within-wafer uniformity by providing uniform gas flow across the surface of each substrate supported in a carrier. In general, the cross-flow liner of the present invention includes a longitudinal bulging section to accommodate a cross-flow injection system so that the liner can be patterned and sized to conform to the wafer carrier. The gap between the liner and the wafer carrier is significantly reduced, and as a result, vortices and stagnation as occurred in prior art furnaces can be reduced or avoided.

FIG. 20 shows a thermal processing apparatus 230 including a cross-flow liner 232 according to one embodiment of the present invention. To simplify description of the invention, elements not closely relevant to the invention are not indicated in the drawing and described. In general, the apparatus 230 includes a vessel 234 that forms a process chamber 236 having a support 238 adapted for receiving a carrier 240 with a batch of wafers 242 held therein. The apparatus 230 includes heat source or furnace 244 for raising temperature of the wafers 242 to the desired temperature for thermal processing. A cross-flow liner 232 is provided to increase the concentration of processing gas or vapor near wafers 242 and reduce contamination of wafers 242 from flaking or peeling of deposits that can form on interior surfaces of the process chamber 236. The liner 232 is patterned to conform to the contour of the wafer carrier 240 and sized to reduce the gap between the wafer carrier 240 and the liner wall. The liner 232 is mounted to the base plate 246 and sealed. A cross-flow injection system 250 is disposed between the liner 232 and the wafer carrier 240. Gases are introduced through a plurality of injection ports or orifices 252 from one side of the wafers 242 and carrier 240 across the surface of the wafers in a laminar flow as described below. A plurality of slots 254 are formed in the liner 232 on the opposite side to exhaust gases or reaction by-product.

The cross-flow liner can be made of any metal, ceramic, crystalline or glass material that is capable of withstanding the thermal and mechanical stresses of high temperature and high vacuum operation, and which is resistant to erosion from gases and vapors used or released during processing. Preferably, the cross-flow liner is made from an opaque, translucent or transparent quartz glass having a sufficient thickness to withstand the mechanical stresses and that resists deposition of process byproducts, thereby reducing potential contamination of the processing environment. In one embodiment, the liner is made from quartz that reduces or eliminates the conduction of heat away from the region or process zone in which the wafers are processed.

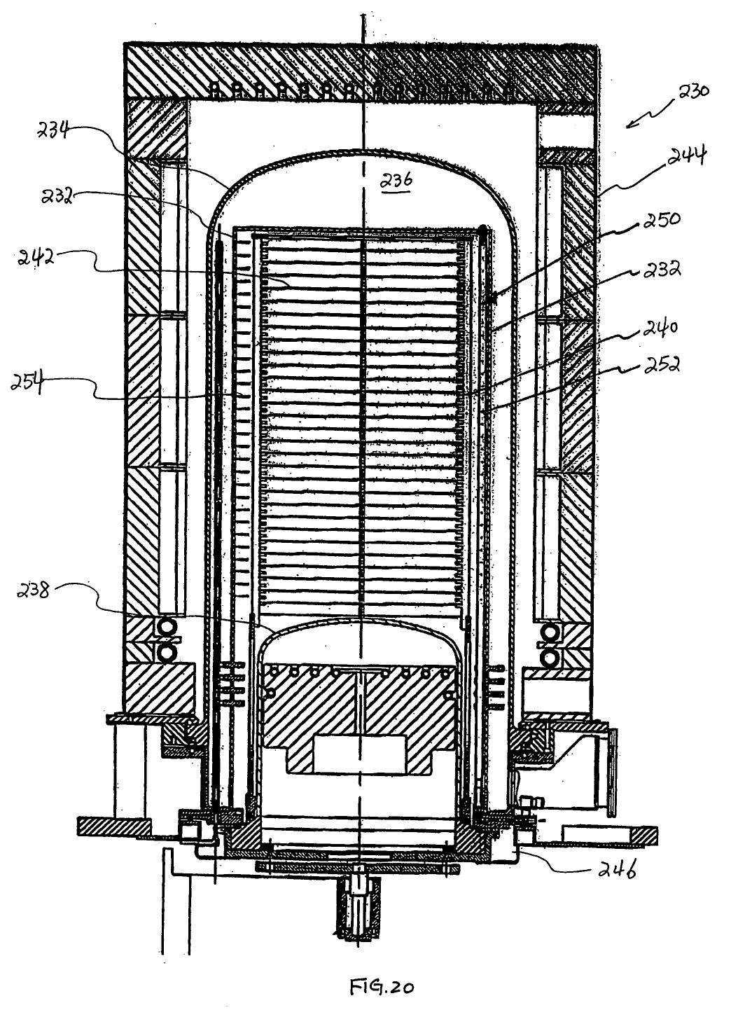

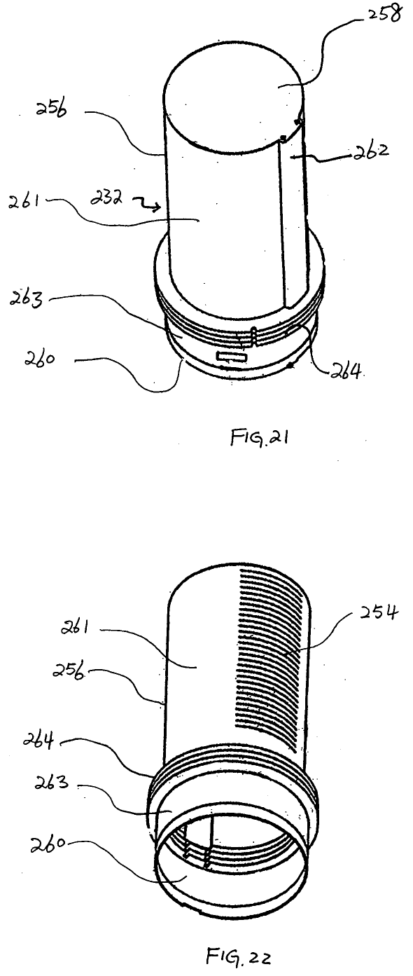

FIGS. 21 and 22 show external views of the cross-flow liner 232 according to one embodiment of the present invention. In general, the cross-flow liner 232 includes a cylinder 256 having a close end 258 and open end 260. The cylinder 256 is provided with a longitudinal bulging section 262 to accommodate a cross-flow injection system (not shown). Preferably the bulging section 262 extends the substantial length of the cylinder 256. A plurality of latitudinal slots 254 are provided longitudinally in the cylinder 256 on the side opposite to the bulging section 262 to exhaust gases and reaction by-products.

The cross-flow liner 232 is sized and patterned to conform to the contour of the wafer carrier 240 and the carrier support 238. In one embodiment, the liner 232 comprises a first section 261 sized to conform to both the wafer carrier 240 and a second section 263 sized to conform to the carrier support 238. The diameter of the first section 261 may differ from the diameter of the second section 263, ie., the liner 232 may be “stepped” to conform to the wafer carrier 240 and carrier support 238 respectively. In one embodiment, the first section 261 of the liner 232 has an inner diameter that constitutes about 104 to 110% of the carrier outer diameter. In another embodiment, the second section 263 of the liner 232 has an inner diameter that constitutes about 115 to 120% of outer diameter of the carrier support 238. The second section 263 may be provided with one or more heat shields 264 to protect seals such as O-rings from being overheated by heating elements.

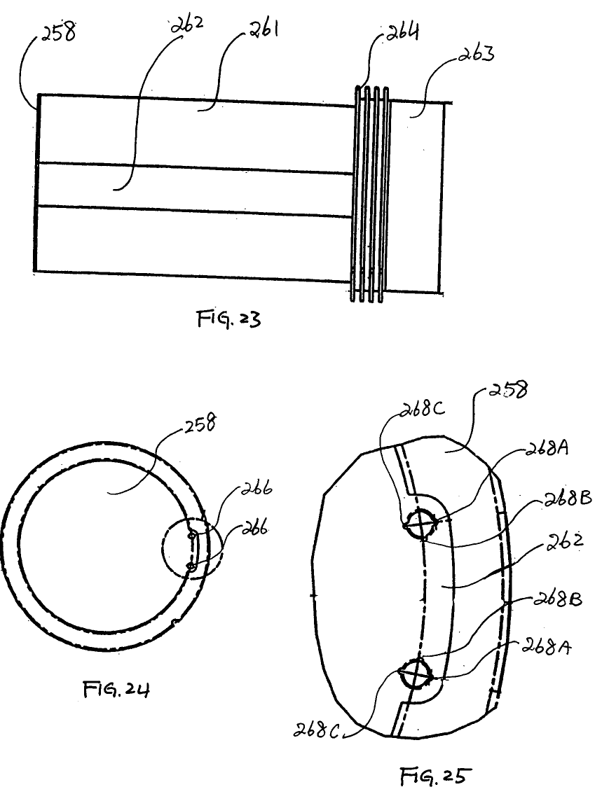

FIG. 23 is a side view of the cross-flow liner 232 showing the step between the first and second sections 261 and 263. The longitudinal bulging section 262 extends the length of the first section 261. An injection system (not shown) is accommodated in the bulging section 232 for introduce one or more gases across the surface of each substrate 242. One or more heat shields 264 can be provided in the second section 263.

FIG. 24 is a top plan view of the cross-flow liner 232 showing the closed end 258 of the cylinder 256 having openings 266 for receiving a cross-flow injection system. As shown in detail in FIG. 25, the openings 266 in the close end 258 have notches 268 for orienting and stabilizing a cross-flow injection system. Although three notches are shown in the openings 266 for illustrative purpose, it should be noted that any number of notches can be formed so that the injection ports in the injection system can be oriented to any direction as desired.

The cross-flow injection system 250 can comprise one or more elongated tubes rotatable about an axis in 360 degrees. U.S. patent application Ser. No. ______ (Attorney Docket No. 33606/US/2), filed concurrently with this application describes one embodiment of an injection system, the disclosure of which is hereby incorporated by reference in its entirety. In the preferred embodiment, the elongated tubes are provided with a plurality of injection ports or orifices 252 longitudinally distributed in the tubes for directing reactant and other gases across the surface of each substrate. In one embodiment, the elongated tube includes an index pin (not shown) for locking the elongated tube in one of the notches 268 in the openings 266 in the close end 258. In one embodiment, the injection ports or orifices 252 in the tubes are formed in line with the index pin. Therefore, when the elongated tube is installed, the pin is locked in one of the notches 268 and the injection ports 252 in the tube are oriented to a direction as indicated by the index pin locked in the notch.

Of advantage, the cross-flow liner of the present invention comprises a bulging section in which a cross-flow injection system can be accommodated therein so that the liner can be made conformal to the contour of the wafer carrier to reduce the gap between the liner and the wafer carrier. This helps reduce vortices and stagnation in the gap regions between the liner inner wall and the wafer carrier, and thus improve flow uniformity, which in turn improves the quality, uniformity, and repeatability of the deposited film.

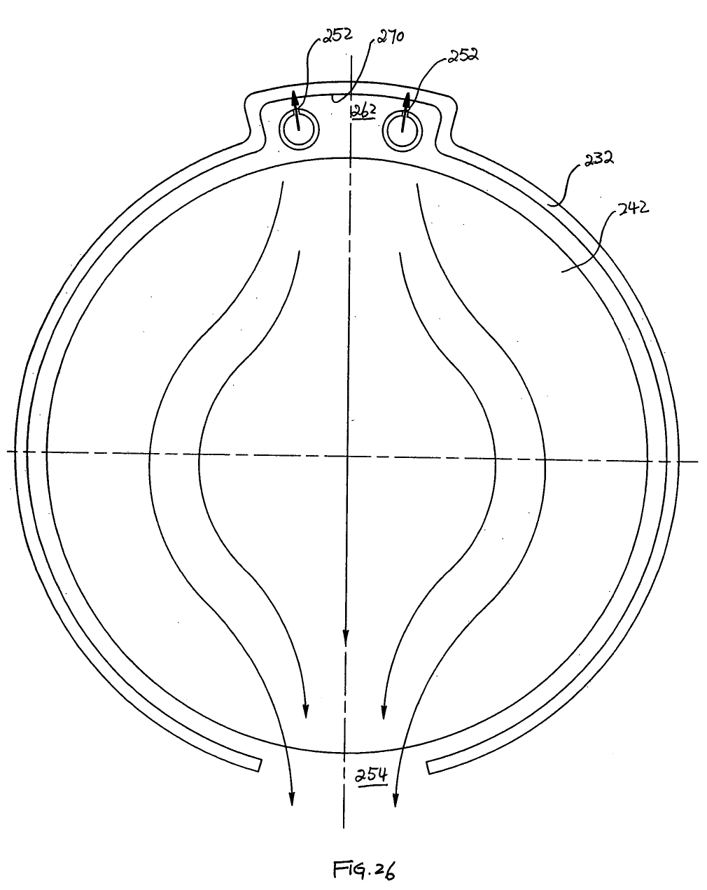

In one embodiment shown in FIG. 23-25, two elongated injection tubes (not shown) are provided in the bulging section 262. Two openings 266 are formed in the close end 258 of the liner 232 to receive the two elongated injection tubes. Notches 268 are formed in the openings 266 to orient the injection ports 252 to a specific direction. Any number of notches can be formed so that the elongated injection tubes can be adjusted in 360 degrees and the injection ports 252 can be oriented in any direction as desired. In one embodiment, the index pin in the elongated tube is received in notch 268A so that the injection ports 252 are oriented to face the inner surface of the liner 232. As indicated in FIG. 26, gases exiting the injection ports 252 impinge the liner wall 270 and mix in the bulging section 262 prior to flowing across the surface of each substrate 242. In another embodiment, the index pin in the elongated tube is received in notch 268B so that the injection ports 252 in each injection tube are oriented to face each other. As indicated in FIG. 27, gases exiting the injection ports 252 impinge each other and mix in the bulging section 262 prior to flowing across the surface of each substrate. In a further embodiment, the index pin in the elongated tube is received in notch 268C so that the injection ports 252 are oriented to face the center of the substrate 242, as indicated in FIG. 28.

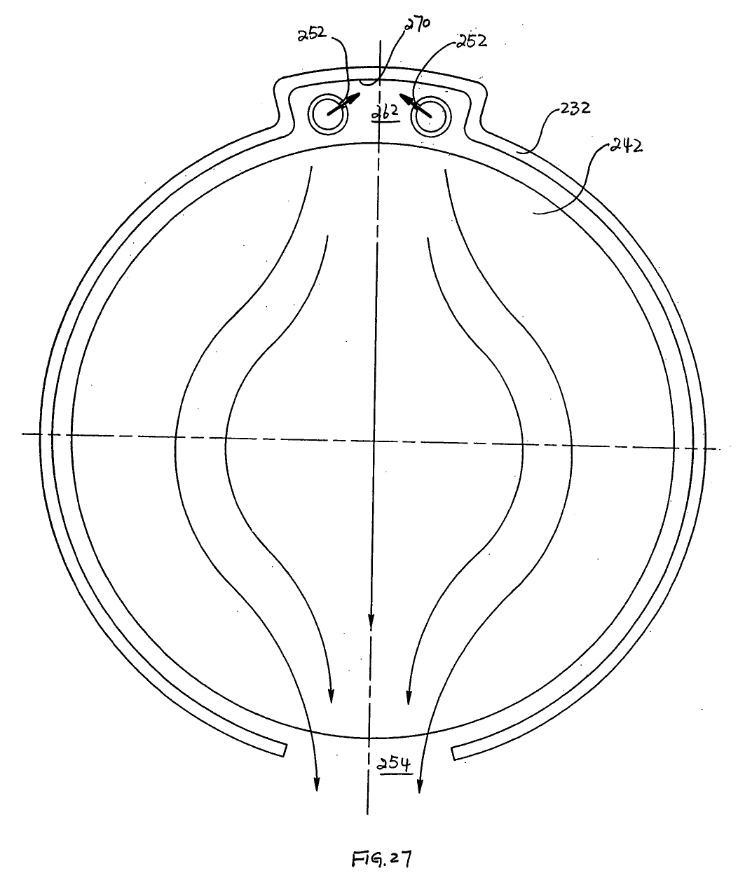

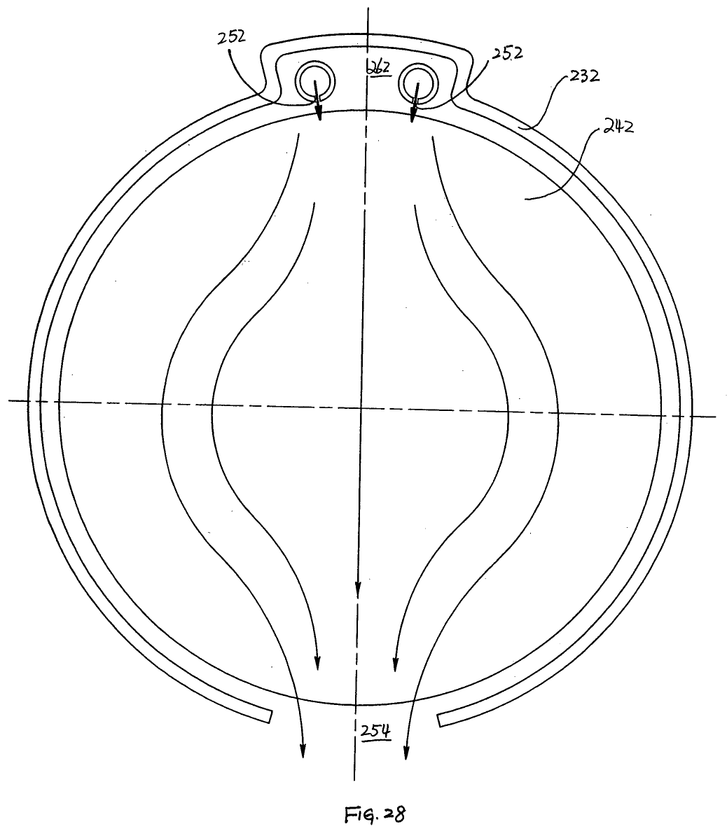

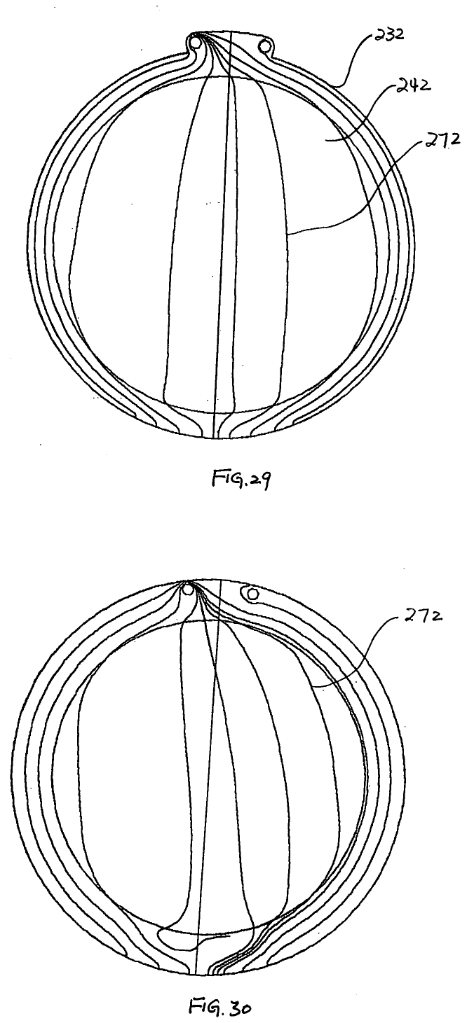

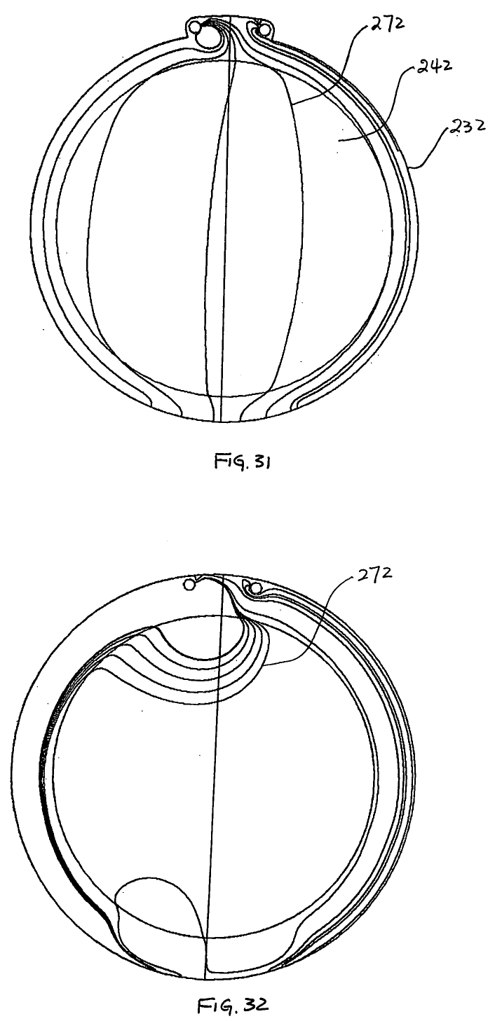

FIGS. 29-34 are “particle trace” graphics representing gas flow lines across the surface of a substrate inside a chamber. The graphics show particle traces 272 from injector ports to the exhaust slot in highly imbalanced flow conditions. The flow momentum out of the first (leftmost) injector ports is ten time higher than the second (rightmost) injector ports. As demonstrated in FIGS. 29, 31 and 33, the cross-flow liner of the present invention has great advantages in providing uniform gas flows across the surface of a substrate as compared with prior art liners. The bulging section in the cross-flow liner of the present invention provides a mixing chamber for the gases exiting the injection ports prior to flowing across the surface of a substrate and thus facilitate momentum transfer of “ballistic mixing” of gases. In contrast, in the chamber with prior art liners without the bulging section of the present invention, the gas flow across the surface of a substrate is irregular and non-uniform, as shown in FIGS. 30, 32 and 34.

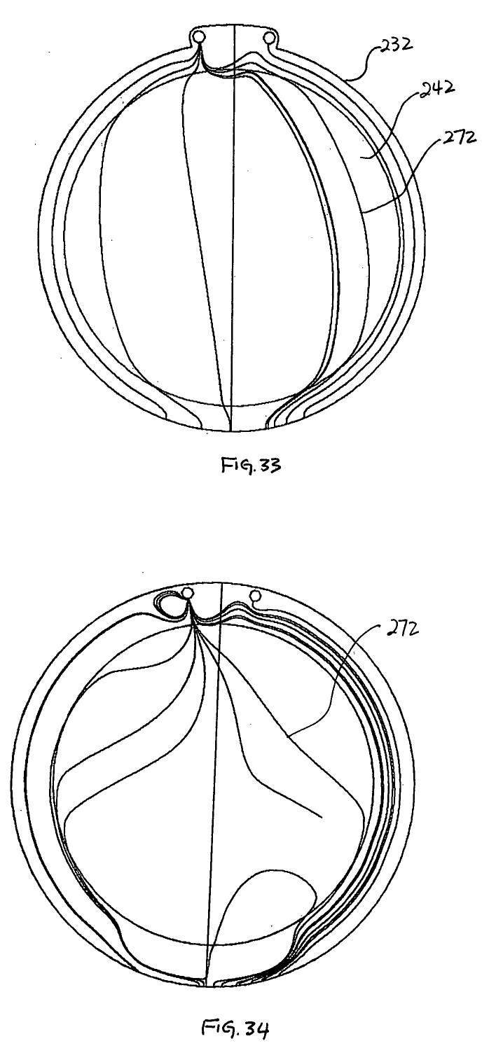

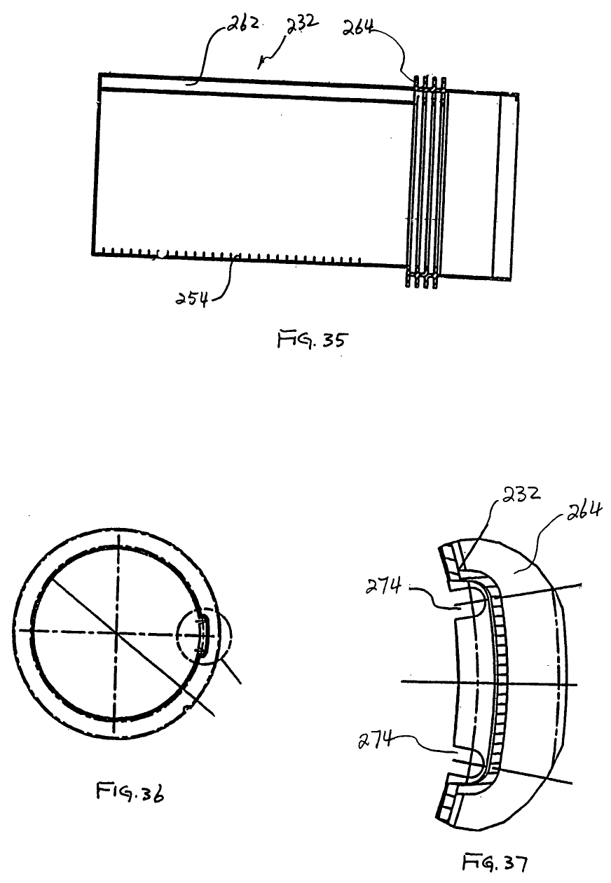

FIG. 35 is an external side view of the cross-flow liner 232 showing a plurality of latitudinal slots 254 through the wall of the liner cylinder. The size and pattern of the slots 254 are predetermined and provided longitudinally on the side opposite to the bulging section 262. In one embodiment, the spacing between and number of the slots in the liner cooperates with the spacing between and number of the injection ports in the injection tubes to facilitate exhausting of gases. FIGS. 36 and 37 are cross-sectional views showing the heat shields 264 in the second section of the liner 232 and two notches 274 for receiving and stabilizing the elongated tubes in the second section of the liner.

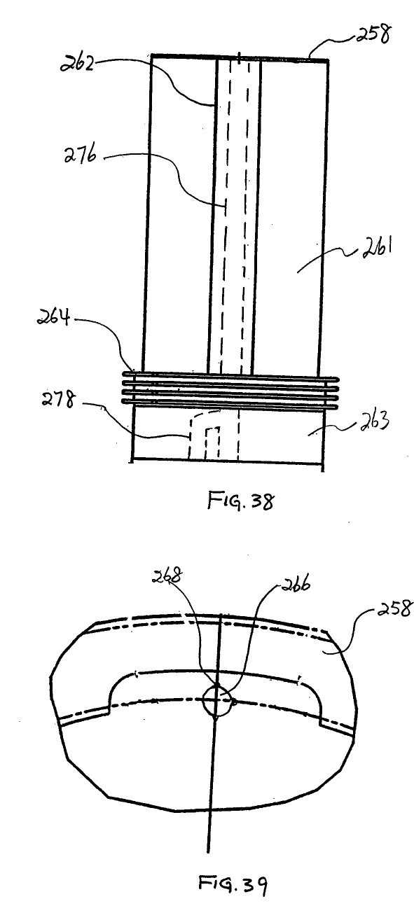

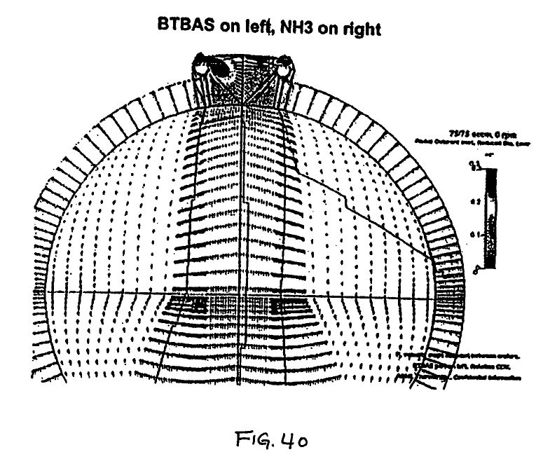

FIGS. 38-39 show another embodiment of the present invention. One elongated injection tube 276 is accommodated in the bulging section 262. A T-tube 278 is connected to the elongated tube 276 in the second section 263 of the liner 232. Two gases are introduced into the elongated tube 276 and T-tube 278 respectively and premixed in the elongated tube 276 prior to exiting the injection ports.

In operation, a vacuum system produces a vacuum pressure in the reaction chamber 236. The vacuum pressure acts in the direction of the elongation of the vessel 234. The cross-flow liner 232 is operative in response to the vacuum pressure to create a second vacuum inside the cross-flow liner 232. The second vacuum pressure acts in a direction transverse the direction of the elongation of the vessel 234 and across the surface of each substrate 242. Two gases, for example a first gas and a second gas are introduced into two elongated tube of the injection system from two different gas sources. The gases exit the injection ports 252 on one side of the wafer 242 and conveyed as laminar flow across the wafer 242 in a path formed between two adjacent wafers. Excessive gases or reaction by-products are exhausted through the latitudinal slots 254 in the liner wall cooperative with the injection ports 252 in the elongated tubes.

FIG. 40 is Computational Fluid Dynamics (CFD) demonstration for a thermal processing apparatus including a cross-flow liner according to one embodiment of the present invention. The cross-flow liner has a reduced diameter and is conformal to the wafer carrier. A cross-flow injection system is accommodated in a bulging section of the liner. The injection system includes two elongated injection tubes each having a plurality of injection ports to introduce reactant or other gases across the surface of each substrate. The injection ports are oriented to face the liner inner surface such that the gases exiting the injection ports impinge the liner wall and mix in the bulging section prior to flowing across the surface of each substrate. In one example, the gases introduced into the two injection tubes were BTBAS (bis tertbutylamino silane) and NH₃ respectively at 75 sccm. FIG. 40 demonstrates a good cross-wafer velocity.

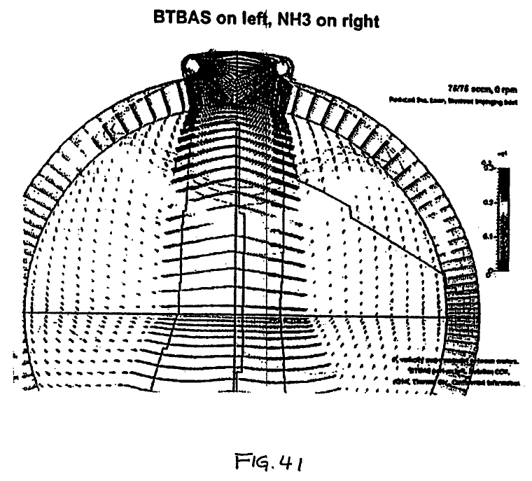

FIG. 41 is Computational Fluid Dynamics (CFD) demonstration for a thermal processing apparatus including a cross-flow liner according to one embodiment of the present invention. The cross-flow liner has a reduced diameter and is conformal to the wafer carrier. A cross-flow injection system is accommodated in a bulging section of the liner. The injection system includes two elongated injection tubes each having a plurality of injection ports to introduce reactant or other gases across the surface of each substrate. The injection ports are oriented to face the center of the substrate. In one example, the gases introduced into the two injection tubes were BTBAS (bis tertbutylamino silane) and NH₃ respectively at 75 sccm. FIG. 41 demonstrates a good cross-wafer velocity.

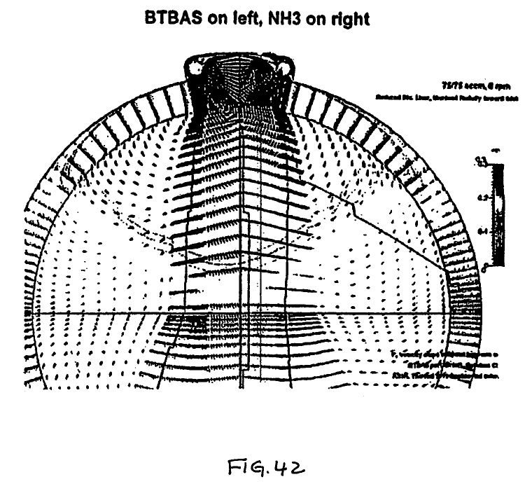

FIG. 42 is Computational Fluid Dynamics (CFD) demonstration for a thermal processing apparatus including a cross-flow liner according to one embodiment of the present invention. The cross-flow liner has a reduced diameter and is conformal to the wafer carrier. A cross-flow injection system is accommodated in a bulging section of the liner. The injection system includes two elongated injection tubes each having a plurality of injection ports to introduce reactant or other gases across the surface of each substrate. The injection ports in each injection tube are oriented to face each other so that the gases exiting the injection ports impinge each other and mix prior to flowing across the surface of each substrate. In one example, the gases introduced into the two injection tubes were BTBAS (bis tertbutylamino silane) and NH₃ respectively at 75 sccm. FIG. 42 demonstrates a good cross-wafer velocity.

The foregoing description of specific embodiments and examples of the invention have been presented for the purpose of illustration and description, and although the invention has been described and illustrated by certain of the preceding examples, it is not to be construed as being limited thereby. They are not intended to be exhaustive or to limit the invention to the precise forms disclosed, and many modifications, improvements and variations within the scope of the invention are possible in light of the above teaching. It is intended that the scope of the invention encompass the generic area as herein disclosed, and by the claims appended hereto and their equivalents.

1. An apparatus for thermally processing a plurality of substrates held in a carrier, said apparatus comprising a liner enclosing the carrier,
wherein said liner comprises a cylinder which is provided with a longitudinal bulging section to accommodate an injection system for introducing one or more gases across the surface of each substrate.

2. The apparatus of claim 1 wherein the liner is patterned and sized to conform to the carrier and has an inner diameter that is about from 104 to 110 percent of a diameter of the carrier.

3. The apparatus of claim 1 wherein the cylinder is provided with a plurality of slots along the length of the cylinder for exhausting gases.

4. The apparatus of claim 1 wherein the cylinder comprises a close end and an open end, said close end is provided with one or more openings to receive the injection system.

5. The apparatus of claim 1 wherein the cylinder comprises a first section and a second section, wherein said first section is patterned and sized to conform to the carrier and has a first diameter that is about from 104 to 110 percent of a diameter of the carrier, and said second section is patterned and sized to conform to a support for the carrier and has a diameter that is about from 115 to 120 percent of a diameter of the support.

6. The apparatus of claim 5 wherein the liner further comprises one or more heat shields disposed around the periphery of the second section of the cylinder.

7. The apparatus of claim 1 wherein said injection system comprises one or more elongated tubes provided with a plurality of injection ports in the tubes.

8. The apparatus of claim 7 wherein the one or more elongated tubes are rotatable about an axis in 360 degrees.

9. A cross-flow liner comprising a cylinder having a close end and an open end, said cylinder is provided with a longitudinal bulging section to accommodate an injection system.

10. The cross-flow liner of claim 9 wherein said cylinder is provided with a plurality of latitudinal slots opposite to the bulging section.

11. The cross-flow liner of claim 9 wherein said close end is provided with one or more openings that are sized to receive the injection system.

12. The cross-flow liner of claim 11 wherein the one or more openings are provided with one or more notches.

13. The cross-flow liner of claim 12 wherein the cylinder comprises a first section having a first diameter and a second section having a second diameter, said first section is provided with a plurality of latitudinal slots opposite the bulging section and said second section is provided with one or more heat shields around the periphery of the second section.
